(19) United States
(12) Patent Application Publication
(10) Pub. No.: US 2025/0143109 A1
(43) Pub. Date: May 1, 2025

(54) Display Substrate, Preparation Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Yao HUANG, Beijing (CN); Xingliang XIAO, Beijing (CN)

(21) Appl. No.: 18/690,258

(22) PCT Filed: Sep. 30, 2022
(86) PCT No.: PCT/CN2022/123125

§ 371 Date: Mar. 7, 2024

(51) Int. Cl. H10K 59/131; G09G 3/3233; H10K 59/12; H10K 59/126; H10K 59/35

(52) U.S. Cl. CPC H10K 59/131; H10K 59/1201; G09G 3/3233; G09G 2300/0426; G09G 2300/0819; G09G 2300/0842; G09G 2300/0861; H10K 59/126; H10K 59/35

(57) ABSTRACT

The display substrate includes a drive circuit layer disposed on a base substrate and a light emitting structure layer, the drive circuit layer includes multiple circuit units, multiple first initial signal lines extending along a first direction, and multiple second initial signal lines and low-voltage power supply lines extending along a second direction, the circuit unit includes at least a pixel drive circuit, the light emitting structure layer includes multiple light emitting devices, the first initial signal line is configured to provide an initial voltage signal to the pixel drive circuit, the low-voltage power supply line is configured to provide a low power supply voltage signal to the light emitting device, the second initial signal line is connected to the first initial signal line, and the first initial signal lines and the second initial signal lines constitute a net-like connecting structure.

### CROSS-REFERENCE TO RELATED APPLICATION

The present application is a U.S. National Phase Entry of International Application No. PCT/CN2022/123125 having an international filing date of Sep. 30, 2022, the entire content of which is hereby incorporated by reference.

### TECHNICAL FIELD

The present disclosure relates to, but is not limited to, the field of display technologies, and particularly to a display substrate and a preparation method therefor, and a display apparatus.

### BACKGROUND

An Organic Light Emitting Diode (OLED) and a Quantum dot Light Emitting Diode (QLED) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In one aspect, the present disclosure provides a display substrate including a drive circuit layer disposed on a base substrate and a light emitting structure layer disposed on a side of the drive circuit layer away from the base substrate, the drive circuit layer includes a plurality of circuit units constituting a plurality of unit rows and a plurality of unit columns, a plurality of first initial signal lines extending along a first direction, and a plurality of second initial signal lines and low-voltage power supply lines extending along a second direction, the first direction intersects with the second direction, a circuit unit includes at least a pixel drive circuit, the pixel drive circuit includes a storage capacitor and a plurality of oxide transistors, the light emitting structure layer includes a plurality of light emitting devices, a first initial signal line is configured to provide an initial voltage signal to the pixel drive circuit, the low-voltage power supply lines are configured to provide a low-power supply voltage signal to the light emitting devices, the second initial signal lines are connected to the first initial signal lines, the first initial signal lines and the second initial signal lines constitute a net-like connecting structure.

In an exemplary implementation mode, the first initial signal line includes a plurality of initial sub-lines disposed at intervals along the first direction, and in at least one circuit unit, the initial sub-lines adjacent in the first direction are connected to each other through initial connection electrodes.

In an exemplary implementation mode, the drive circuit layer includes a plurality of conductive layers, the initial sub-line and the initial connection electrode are disposed in different conductive layers, in at least one circuit unit, the initial connection electrode is connected to the initial sub-line through a via.

In an exemplary implementation mode, in at least one circuit unit, the second initial signal line is connected to the initial connection electrode.

In an exemplary implementation mode, the drive circuit layer includes a plurality of conductive layers, the initial connection electrode and the second initial signal line are disposed in different conductive layers, in at least one circuit unit, the second initial signal line is connected to the initial connection electrode through a via.

In an exemplary implementation mode, the pixel drive circuit includes a first transistor, a second transistor, a third transistor, a fourth transistor, a fifth transistor, and a sixth transistor, in at least one circuit unit, a first electrode of the first transistor is connected to the first initial signal line, a second electrode of the first transistor is connected to a second plate of the storage capacitor and a second electrode of the sixth transistor, a first electrode of the second transistor is connected with a first plate of the storage capacitor, a second electrode of the second transistor is connected to a first electrode of the third transistor, a first electrode of the fourth transistor is connected to a data signal line, a second electrode of the fourth transistor is connected to a second electrode of the third transistor, a first electrode of the fifth transistor is connected to a first power supply line, a second electrode of the fifth transistor is connected with the first electrode of the third transistor, a first electrode of the sixth transistor is connected with the second electrode of the third transistor, and a second electrode of the sixth transistor is connected to the light emitting device.

In an exemplary implementation mode, in at least one circuit unit, the first transistor, the fourth transistor, and the sixth transistor are disposed at a side of the storage capacitor in the second direction, and the second transistor and the fifth transistor are disposed at a side of the storage capacitor in an opposite direction of the second direction.

In an exemplary implementation mode, in at least one circuit unit, the fourth transistor is disposed at a side of the storage capacitor in the second direction, the sixth transistor is disposed at a side of the fourth transistor away from the storage capacitor, the first transistor is disposed at a side of the sixth transistor away from the storage capacitor, the second transistor is disposed at a side of the storage capacitor in an opposite direction of the second direction, and the fifth transistor is disposed at a side of the second transistor away from the storage capacitor.

In an exemplary implementation mode, in at least one circuit unit, the first transistor includes at least a first active layer, the sixth transistor includes at least a sixth active layer, and a second region of the first active layer and a first region of the sixth active layer are of an interconnected integral structure.

In an exemplary implementation mode, in at least one circuit unit, the second transistor includes at least a second active layer, the third transistor includes at least a third active layer, the fourth transistor includes at least a fourth active layer, the second active layer and the fourth active layer have a shape of a strip extending along the first direction, the third active layer has a shape of a strip extending along the second direction, a first region of the third active layer and a second region of the second active layer are of an interconnected integral structure, and a second region of the third active layer and a second region of the fourth active layer are of an interconnected integral structure.

In an exemplary implementation mode, in at least one circuit unit, the third transistor includes at least a bottom gate electrode and a top gate electrode, the bottom gate electrode is connected to a second electrode of the fourth transistor and a first electrode of the sixth transistor, respectively, and the top gate electrode and a first plate of the storage capacitor are of an integral structure.

In an exemplary implementation mode, the drive circuit layer further includes a first scan signal line, a second scan signal line, a third scan signal line, a first light emitting control line and a second light emitting control line extending along the first direction, in at least one circuit unit, the first scan signal line is connected to a top gate electrode of the first transistor, the second scan signal line is connected to a top gate electrode of the fourth transistor, the third scan signal line is connected to a top gate electrode of the second transistor, the first light emitting control line is connected to a top gate electrode of the sixth transistor, and the second light emitting control line is connected to a top gate electrode of the fifth transistor.

In an exemplary implementation mode, in at least one circuit unit, the second scan signal line is located at a side of the storage capacitor in the second direction, the first light emitting control line is located at a side of the second scan signal line away from the storage capacitor, the first scan signal line is located at a side of the first light emitting control line away from the storage capacitor, the third scan signal line is located at a side of the storage capacitor in an opposite direction of the second direction, and the second light emitting control line is located at a side of the third scan signal line away from the storage capacitor.

In an exemplary implementation mode, in at least one circuit unit, the first initial signal line is disposed at a side of the first scan signal line away from the storage capacitor.

In an exemplary implementation mode, the drive circuit layer includes at least a shielding conductive layer, a first conductive layer, a second conductive layer, a third conductive layer and a fourth conductive layer arranged sequentially in a direction away from the base substrate, the shielding conductive layer includes at least bottom gate electrodes of a plurality of oxide transistors, the first conductive layer includes at least a first plate of the storage capacitor and top gate electrodes of the plurality of oxide transistors, the second conductive layer includes at least a second plate of the storage capacitor and the first initial signal lines, the third conductive layer includes at least first electrodes and second electrodes of the plurality of oxide transistors, and the fourth conductive layer includes at least the second initial signal lines and the low-voltage power supply lines.

In an exemplary implementation mode, the plurality of unit columns includes at least a first unit column, a second unit column, and a third unit column, pixel drive circuits of a plurality of circuit units in the first unit column are connected to a red light emitting device that emits red light, pixel drive circuits of a plurality of circuit units in the second unit column are connected to a green light emitting device that emits green light, pixel drive circuits of a plurality of circuit units in the third unit column are connected to a blue light emitting device that emits blue light, the low-voltage power supply lines are provided in the first unit column and the second unit column, and the second initial signal lines are provided in the third unit column.

In another aspect, the present disclosure further provides a display apparatus, including the display substrate described above.

In another aspect, the present disclosure further provides preparation method for a display substrate, including:
forming a drive circuit layer on a base substrate, wherein the drive circuit layer includes a plurality of circuit units constituting a plurality of unit rows and a plurality of unit columns, a plurality of first initial signal lines extending along a first direction, and a plurality of second initial signal lines and low-voltage power supply lines extending along a second direction, the first direction intersects with the second direction, a circuit unit includes at least a pixel drive circuit, the pixel drive circuit includes a storage capacitor and a plurality of oxide transistors, a first initial signal line is configured to provide an initial voltage signal to the pixel drive circuit, the second initial signal lines are connected to the first initial signal lines, the first initial signal lines and the second initial signal lines constitute a net-like connecting structure;
forming a light emitting structure layer on the drive circuit layer, wherein the light emitting structure layer includes a plurality of light emitting devices, and the low-voltage power supply lines are configured to provide a low-power supply voltage signal to the light emitting devices.

After the drawings and the detailed descriptions are read and understood, the other aspects may be comprehended.

### BRIEF DESCRIPTION OF DRAWINGS

The accompany drawings are used to provide further understanding of the technical solution of the present disclosure, and form a part of the description. The accompany drawings and embodiments of the present disclosure are adopted to explain the technical solution of the present disclosure, but do not form limits to the technical solution of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit in accordance with an exemplary embodiment of the present disclosure.

FIG. 5 is a schematic diagram of a planar structure of a display substrate according to an exemplary embodiment of the present disclosure.

FIG. 6 is a schematic diagram after a pattern of a shielding conductive layer is formed according to an embodiment of the present disclosure.

FIGS. 7A and 7B are schematic diagrams obtained after a pattern of a semiconductor layer is formed according to an embodiment of the present disclosure.

FIGS. 8A and 8B are schematic diagrams obtained after a pattern of a first conductive layer is formed according to an embodiment of the present disclosure.

FIGS. 9A and 9B are schematic diagrams obtained after a pattern of a second conductive layer is formed in accordance with an embodiment of the present disclosure.

FIG. 10 is a schematic diagram obtained after a pattern of a fourth insulation layer is formed according to an embodiment of the present disclosure.

FIGS. 11A and 11B are schematic diagrams obtained after a pattern of a third conductive layer is formed in accordance with an embodiment of the present disclosure.

FIG. 12 is a schematic diagram obtained after a pattern of a first planarization layer is formed according to an embodiment of the present disclosure.

FIGS. 13A and 13B are schematic diagrams obtained after a pattern of a fourth conductive layer is formed in accordance with an embodiment of the present disclosure.

FIG. 14 illustrates a schematic diagram of a planar structure of another display substrate according to an exemplary embodiment of the present disclosure.

FIG. 15 is a schematic diagram of a planar structure of a still further display substrate according to an exemplary embodiment of the present disclosure.

FIG. 16 is a schematic diagram of a planar structure of a still further display substrate according to an exemplary embodiment of the present disclosure.

FIG. 17 is a schematic diagram of a planar structure of a still further display substrate according to an exemplary embodiment of the present disclosure.

FIG. 18 is a schematic diagram of a planar structure of a still further display substrate according to an exemplary embodiment of the present disclosure.

FIG. 19 is a schematic diagram of a planar structure of a still further display substrate according to an exemplary embodiment of the present disclosure.

FIG. 20 is a schematic diagram of a planar structure of a still further display substrate according to an exemplary embodiment of the present disclosure.

FIG. 21 is a schematic diagram of a planar structure of a still further display substrate according to an exemplary embodiment of the present disclosure.

FIG. 22 is a schematic diagram of a planar structure of a still further display substrate according to an exemplary embodiment of the present disclosure.

FIG. 23 is a schematic diagram of a planar structure of a still further display substrate according to an exemplary embodiment of the present disclosure.

Reference signs are described as follows.

| | | |
|---|---|---|
| 10-base substrate; | 11-first shielding line; | 12-second shielding line; |
| 13-third shielding line; | 14-fourth shielding line; | 15-fifth shielding line; |
| 16-shielding electrode; | 20-drive circuit layer; | 21-first active layer; |
| 22-second active layer; | 23-third active layer; | 24-fourth active layer; |
| 25-fifth active layer; | 26-sixth active layer; | 27-seventh active layer; |
| 30-light emitting structure | 31-first scan signal line; | 32-second scan signal line |
| layer; | | |
| 33-third scan signal line; | 34-first light emitting control | 35-second light emitting |
| | line; | control line; |
| 36-first plate; | 40-encapsulation structure | 41-initial sub-line; |
| | layer; | |
| 42-second plate; | 43-opening; | 50-storage capacitor; |
| 51-first connection electrode; | 52-second connection | 53-third connection electrode; |
| | electrode; | |
| 54-fourth connection | 55-fifth connection electrode; | 56-sixth connection electrode; |
| electrode; | | |
| 57-seventh connection | 58-initial connection | 61-anode connection |
| electrode; | electrode; | electrode; |
| 62-first power supply line; | 63-data signal line; | 70-first initial signal line; |
| 80-second initial signal line; | 90-low-voltage power supply | 91-first insulation layer; |
| | line; | |
| 92-second insulation layer; | 93-third insulation layer; | 94-fourth insulation layer; |
| 95-fifth insulation layer; | 96-first planarization layer; | 97-second planarization layer; |
| 101-first shielding block; | 102-second shielding block; | 103-third shielding block; |
| 104-fourth shielding block; | 105-fifth shielding block; | 111-shield block; |
| 121-first capacitor block; | 122-second capacitor block. | |

### DETAILED DESCRIPTION

To make the objectives, technical solutions, and advantages of the present disclosure clearer, the embodiments of the present disclosure will be described in detail below in combination with the accompany drawings. It is to be noted that the implementations may be implemented in various forms. Those of ordinary skill in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other in case of no conflicts.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in quantities but only to avoid the confusion of composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the drawings, not to indicate or imply that involved devices or elements are needed to have specific orientations and be structured and operated with the specific orientations but only to easily and simply describe the present specification, and thus should not be understood as limits to the present disclosure. The positional relationships between the composition elements may be changed as appropriate according to the direction by which each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, the term may be fixed connection, or detachable connection, or integral connection. The term may be mechanical connection or electric connection. The term may be direct connection, or indirect connection through an intermediate, or communication inside two elements. Those of ordinary skill in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. It is to be noted that in the specification, the channel region refers to a main region that a current flows through.

In the specification, a first electrode may be the drain electrode, and a second electrode may be the source electrode. Alternatively, the first electrode may be a source electrode, and the second electrode may be a drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode”, as well as the “source terminal” and the “drain terminal”, are interchangeable in the specification.

In the specification, “electric connection” includes connection of the composition elements through an element with a certain electric action. “An element with a certain electric action” is not particularly limited as long as electric signals between the connected composition elements may be sent and received. Examples of “an element with a certain electric action” not only include an electrode and a line, but also include a switch element such as a transistor, a resistor, an inductor, a capacitor, another element with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation thin film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc. In the present disclosure, “about” refers to that a boundary is not defined so strictly and numerical values within process and measurement error ranges are allowed.

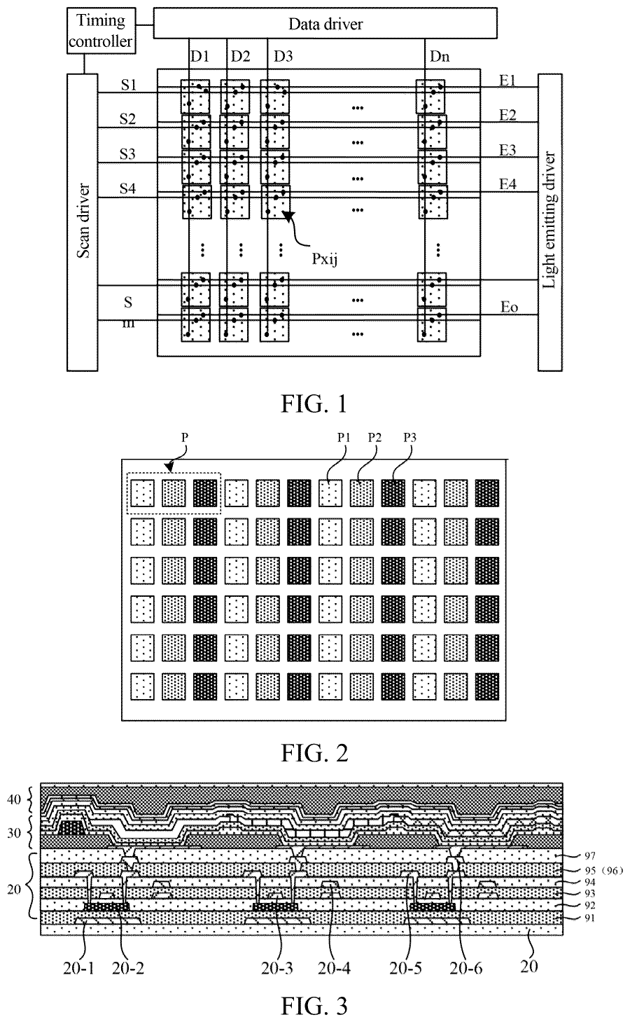

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include multiple sub-pixels Pxij, wherein i and j may be natural numbers. At least one sub-pixel Pxij may include a circuit unit and a light emitting device connected to the circuit unit, and the circuit unit may include a pixel drive circuit which is connected with the scan signal line, the light emitting signal line and a data signal line. In an exemplary implementation, the timing controller may provide a grayscale value and a control signal suitable for the specification of the data signal driver to the data signal driver, may provide a clock signal, a scan start signal, etc. suitable for the specification of the scan driver to the scan driver, and may provide a clock signal, an emission stop signal, etc. suitable for the specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value by using the clock signal and apply a data voltage corresponding to the grayscale value to the data signal lines D1 to Dn by taking a unit row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a planar structure of a display substrate. As shown in FIG. 2, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting device, wherein the circuit unit may at least include a pixel drive circuit, the pixel drive circuit is connected to a scan signal line, a light emitting signal line, and a data signal line respectively, and the pixel drive circuit is configured to receive a data voltage transmitted by the data signal line and output a corresponding current to the light emitting device under control of the scan signal line and the light emitting signal line. The light emitting device in each sub-pixel is connected with a pixel drive circuit of a sub-pixel where the light emitting device is located, and is configured to emit light with corresponding brightness in response to a current output by the pixel drive circuit of the sub-pixel where the light emitting device is located.

In an exemplary implementation mode, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged side by side horizontally, side by side vertically, or in a manner like a Chinese character “ [symbol] ”, etc., which is not limited here in the present disclosure.

In an exemplary implementation, the pixel unit may include four sub-pixels, and the four sub-pixels may be arranged horizontally, vertically or squarely, which is not limited here in the present disclosure.

FIG. 3 is a schematic diagram of a sectional structure of a display substrate, which illustrates a structure of three sub-pixels. As shown in FIG. 3, on a plane perpendicular to the display substrate, the display substrate may include a drive circuit layer 20 arranged on a base substrate 10, a light emitting structure layer 30 arranged at a side of the drive circuit layer 20 away from the base substrate 10, and an encapsulation structure layer 40 arranged at a side of the light emitting structure layer 30 away from the base substrate 10. In some possible implementations, the display substrate may include other film layers, such as a touch structure layer, etc., which is not limited here in the present disclosure.

In an exemplary implementation mode, on a plane parallel to the display substrate, the drive circuit layer 20 may include a plurality of circuit units, each of which may include a pixel drive circuit, a scan signal line, a light emitting control line, a data signal line, a first power supply line, etc., connected to the pixel drive circuit, and the pixel drive circuit may include at least a plurality of transistors and a storage capacitor. In a plane perpendicular to the display substrate, the drive circuit layer 20 may include a shielding conductive layer 20-1, a first insulation layer 91, a semiconductor layer 20-2, a second insulation layer 92, a first conductive layer 20-3, a third insulation layer 93, a second conductive layer 20-4, a fourth insulation layer 94, a third conductive layer 20-5, a fifth insulation layer 95, a first planarization layer 96, a fourth conductive layer 20-6, and a second planarization layer 97 arranged sequentially on the base substrate. The shielding conductive layer 20-1 may include at least a plurality of shielding lines, the semiconductor layer 20-2 may include at least active layers of the plurality of transistors, the first conductive layer 20-3 may include at least a first plate of the storage capacitor, the second conductive layer 20-4 may include at least a second plate of the storage capacitor, the third conductive layer 20-5 may include at least first electrodes and second electrodes of the plurality of transistors, and the fourth conductive layer 20-6 may include at least an anode connection electrode.

In an exemplary implementation mode, the light emitting structure layer 30 may include a plurality of light emitting devices, each light emitting device can at least include an anode, a pixel definition layer, an organic light emitting layer and a cathode, wherein the anode is connected with a pixel drive circuit, the organic light emitting layer is connected with the anode, and the cathode is connected with the organic light emitting layer, and the organic light emitting layer emits light of corresponding color under drive of the anode and the cathode. The encapsulation layer 40 may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of an inorganic material/an organic material/an inorganic material and ensure that external water vapor cannot enter the light emitting structure layer 30.

In an exemplary implementation mode, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, one or more layers of hole injection layers, hole transport layers, electron block layers, hole block layers, electron transport layers, and electron injection layers of all sub-pixels may be a common layer communicated together. Emitting layers of adjacent circuit units may be overlapped slightly, or may be mutually isolated.

With gradual maturity of an OLED display technology and continuous improvement of a yield, a cost of an OLED display apparatus is continuously decreasing, which enables the OLED display apparatus to be gradually applied in more fields, e.g., a field of large and medium-sized electronic products. With an increase in size of the display substrate, the yield of the display substrate using Low Temperature Poly-Silicon (LTPS) thin film transistors decreases, resulting in a relatively high cost. Therefore, display substrates entirely using oxide thin film transistors become to be valued.

Exemplary embodiments of the present disclosure provide a display substrate including a drive circuit layer disposed on a base substrate and a light emitting structure layer disposed on a side of the drive circuit layer away from the base substrate, the drive circuit layer includes a plurality of circuit units constituting a plurality of unit rows and a plurality of unit columns, a plurality of first initial signal lines extending along a first direction, and a plurality of second initial signal lines and low-voltage power supply lines extending along a second direction, the first direction intersects with the second direction, a circuit unit includes at least a pixel drive circuit, the pixel drive circuit includes a storage capacitor and a plurality of oxide transistors, the light emitting structure layer includes a plurality of light emitting devices, a first initial signal line is configured to provide an initial voltage signal to the pixel drive circuit, the low-voltage power supply lines are configured to provide a low-power supply voltage signal to the light emitting devices, the second initial signal lines are connected to the first initial signal lines, the first initial signal lines and the second initial signal lines constitute a net-like connecting structure.

In an exemplary implementation mode, the first initial signal line includes a plurality of initial sub-lines disposed at intervals along the first direction, and in at least one circuit unit, the initial sub-lines adjacent in the first direction are connected to each other through initial connection electrodes.

In an exemplary implementation mode, in at least one circuit unit, the second initial signal line is connected to the initial connection electrode.

In an exemplary implementation mode, the plurality of unit columns includes at least a first unit column, a second unit column, and a third unit column, pixel drive circuits of a plurality of circuit units in the first unit column are connected to a red light emitting device that emits red light, pixel drive circuits of a plurality of circuit units in the second unit column are connected to a green light emitting device that emits green light, pixel drive circuits of a plurality of circuit units in the third unit column are connected to a blue light emitting device that emits blue light, the low-voltage power supply lines are provided in the first unit column and the second unit column, and the second initial signal lines are provided in the third unit column.

The display substrate of the present embodiment will now be described with some examples.

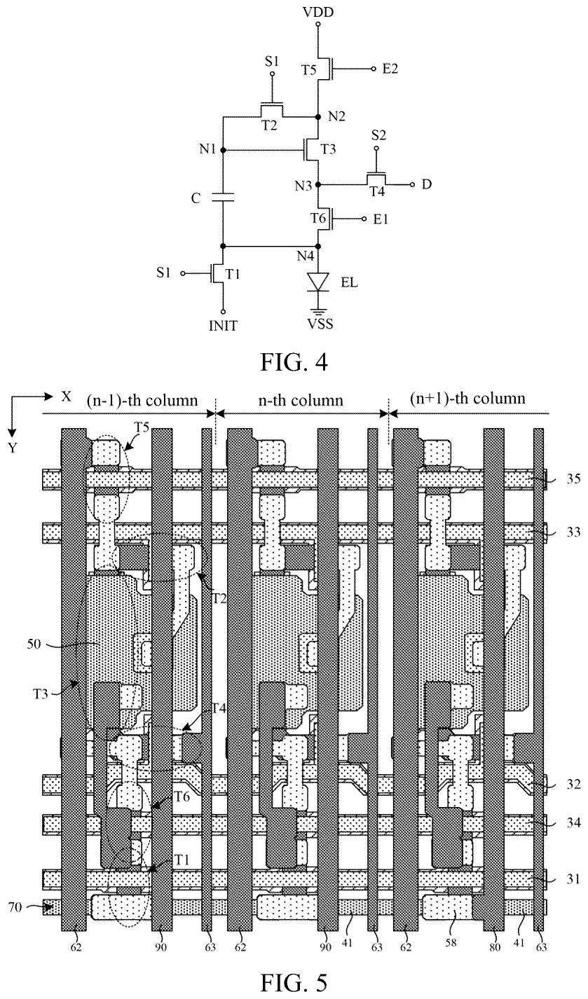

FIG. 4 is an equivalent circuit diagram of a pixel drive circuit according to an exemplary embodiment of the present disclosure. In an exemplary implementation mode, the pixel drive circuit may have a structure of 3T1C, 4T1C, 5T1C, 5T2C, 6T1C, 7T1C, or 8T1C. As shown in FIG. 4, the pixel drive circuit of an exemplary embodiment of the present disclosure may include six transistors (a first transistor T1 to a sixth transistor T6) and one storage capacitor C, and the pixel drive circuit is connected to eight signal lines (a first scan signal line S1, a second scan signal line S2, a first light emitting signal line E1, a second light emitting signal line E2, an initial signal line INIT, a data signal line D, a first power supply line VDD and a second power supply line VSS), respectively.

In an exemplary implementation, the pixel drive circuit may include a first node N1, a second node N2, a third node N3 and a fourth node N4. The first node N1 is respectively connected to a first electrode of the second transistor T2, a gate electrode of the third transistor T3 and a first plate of the storage capacitor C, the second node N2 is respectively connected to a second electrode of the second transistor T2, a first electrode of the third transistor T3 and a second electrode of the fifth transistor T5, the third node N3 is respectively connected to a second electrode of the third transistor T3, a second electrode of the fourth transistor T4 and a first electrode of the sixth transistor T6, the fourth node N4 is respectively connected to a second electrode of the first transistor T1, a second electrode of the sixth transistor T6 and a second plate of the storage capacitor C, and the fourth node N4 is also connected to a first electrode of the light emitting device EL.

In an exemplary implementation mode, the first plate of the storage capacitor C is connected to the first node N1, and the second plate of the storage capacitor C is connected to the fourth node N4, i.e., a first end of the storage capacitor C is connected to the gate electrode of the third transistor T3, and a second end of the storage capacitor C is connected to the first electrode of the light emitting device EL.

In an exemplary implementation mode, the gate electrode of the first transistor T1 is connected to the first scan signal line S1, the first electrode of the first transistor T1 is connected to the initial signal line INIT, and the second electrode of the first transistor T1 is connected to the second plate of the storage capacitor C and the fourth node N4. When an on-level scan signal is applied to the first scan signal line S1, the first transistor T1 is turned on, and initialization voltages are transmitted to the second plate of the storage capacitor C and the first electrode of the light emitting device EL, respectively, thereby realizing initialization of the storage capacitor C and the light emitting device EL.

In an exemplary implementation, a gate electrode of the second transistor T2 is connected to the first scan signal line S1, a first electrode of the second transistor T2 is connected to the first node N1, and a second electrode of the second transistor T2 is connected to the second node N2. When a scan signal with a turn-on level is applied to the first scan signal line S1, the second transistor T2 enables the gate electrode of the third transistor T3 to be connected to the first electrode of the third transistor T3.

In an exemplary implementation, the gate electrode of the third transistor T3 is connected to the first node N1, i.e., the gate electrode of the third transistor T3 is connected to the first plate of the storage capacitor C, the first electrode of the third transistor T3 is connected to the second node N2, and the second electrode of the third transistor T3 is connected to the third node N3. The third transistor T3 may be referred to as a drive transistor, and the third transistor T3 determines a magnitude of a drive current flowing between the first power supply line VDD and the light emitting device according to a potential difference between the gate electrode and the first electrode of the third transistor T3.

In an exemplary implementation, a gate electrode of the fourth transistor T4 is connected to the second scan signal line S2, a first electrode of the fourth transistor T4 is connected to the data signal line D, and a second electrode of the fourth transistor T4 is connected to the third node N3. When a scan signal with a turn-on level is applied to the second scan signal line S2, the fourth transistor T4 enables a data voltage of the data signal line D to be input to the third node N3.

In an exemplary implementation, a gate electrode of the fifth transistor T5 is connected to the second light emitting signal line E2, a first electrode of the fifth transistor T5 is connected to the first power supply line VDD, and a second electrode of the fifth transistor T5 is connected to the second node N2. A gate electrode of the sixth transistor T6 is connected to the first light emitting signal line E1, a first electrode of the sixth transistor T6 is connected to the third node N3, and a second electrode of the sixth transistor T6 is connected to the fourth node N4. When an on-level light emitting signal is applied to the first light emitting signal line E1 and the second light emitting signal line E2, the fifth transistor T5 and the sixth transistor T6 enable the light emitting device to emit light by forming a driving current path between the first power supply line VDD and the light emitting device.

In an exemplary implementation, the light emitting device EL may be an OLED including a first electrode (anode), an organic light emitting layer, and a second electrode (cathode), which are stacked, or may be a QLED including a first electrode (anode), a quantum dot light emitting layer, and a second electrode (cathode), which are stacked.

In an exemplary implementation, the six transistors of the pixel drive circuit may be N-type transistors. Use of a same type of transistors in a pixel drive circuit may simplify a process flow, reduce process difficulties of a display substrate, and improve a yield of products.

In an exemplary implementation, the six transistors of the pixel drive circuit may be oxide thin film transistors. An active layer of the oxide thin film transistor may be made of an oxide semiconductor (Oxide). The oxide thin film transistor has advantages of a low leakage current and so on. Using a display substrate equipped with an oxide thin film transistor may achieve low frequency driving, reduce power consumption, and improve display quality.

In an exemplary implementation, a second electrode of the light emitting device EL is connected to a second power supply line VSS, a first power supply line VDD may be configured to provide a constant first voltage signal to the pixel drive circuit, and the second power supply line VSS may be configured to provide a constant second voltage signal to the pixel drive circuit, and the first voltage signal is greater than the second voltage signal, and the initial signal line INIT may be configured to provide an initial voltage signal to the pixel drive circuit. The initial voltage signal may be a constant voltage signal which may be between a first voltage signal provided by the first power supply line VDD and a second voltage signal provided by the second power supply line VSS, which is not limited here in the present disclosure.

In some examples, taking a case in which the first transistor T1 to the sixth transistor T6 included in the pixel drive circuit are all N-type transistors as an example, the working process of the pixel drive circuit may include the following stages.

A first stage A1 is referred to as an initialization stage. A high-level signal provided by the first scan signal line S1 turns on the first transistor T1 and the second transistor T2, and a high-level signal provided by the second light emitting signal line E2 turns on the fifth transistor T5. The first transistor T1 is turned on so that the initial voltage signal provided by the initial signal line INIT is provided to the fourth node N4 and the second plate of the storage capacitor C, to initialize the storage capacitor C and the light emitting device EL, clear the original data voltage in the storage capacitor C, and clear a pre-stored voltage of the first electrode of the light emitting device EL, and initialization is completed, the light emitting device EL does not emit light. The second transistor T2 is turned on so that the first node N1 and the second node N2 are connected, and the fifth transistor T5 is turned on so that the first voltage signal output by the first power supply line VDD is charged into the first plate of the storage capacitor C through the fifth transistor T5, the second node N2 and the first node N1. Since the first plate of the storage capacitor C is at a high level, the third transistor T3 is turned on.

A second stage A2 is referred to as a data writing stage or a threshold compensation stage. The second scan signal line S2 provides a high-level signal to turn on the fourth transistor T4. The fourth transistor T4 is turned on so that the data voltage output from the data signal line D is provided to the first node N1 through the third node N3, the turned-on third transistor T3, the second node N2 and the turned-on second transistor T2, and the difference between the data voltage output from the data signal line D and the threshold voltage of the third transistor T3 is charged into the first plate of the storage capacitor C.

The third stage A3 is referred to as a light-emitting stage. The first light emitting control line E1 and the second light emitting signal line E2 supply high-level signals to turn on the fifth transistor T5 and the sixth transistor T6, and the first voltage signal output from the first power supply line VDD provides a driving voltage to the first electrode of the light emitting element EL through the turned-on fifth transistor T5, the third transistor T3 and the sixth transistor T6 to drive the light emitting element EL to emit light.

In a drive process of the pixel drive circuit, the current flowing through the light emitting element EL is independent of the threshold voltage of the third transistor T3, so that the pixel drive circuit can better compensate the threshold voltage of the third transistor T3.

FIG. 5 is a schematic diagram of a planar structure of a display substrate according to an exemplary embodiment of the present disclosure, illustrating a planar structure of pixel drive circuits in three circuit units in one unit row. In an exemplary implementation, in a direction perpendicular to the display substrate, the display substrate may include a drive circuit layer arranged on a base substrate, a light emitting structure layer arranged on a side of the drive circuit layer away from the base substrate, and an encapsulation structure layer arranged on a side of the light emitting structure layer away from the base substrate. In a direction parallel to the display substrate, the drive circuit layer may include circuit units constituting a plurality of unit rows and a plurality of unit columns, at least one circuit unit may include at least a pixel drive circuit, and at least one pixel drive circuit may include a storage capacitor and a plurality of oxide transistors. The light emitting structure layer includes a plurality of light emitting devices, and at least one light emitting device may include an anode, an organic light emitting layer, and a cathode.

In an exemplary implementation mode, the drive circuit layer further includes a plurality of first initial signal lines 70 extending along the first direction X, a plurality of second initial signal lines 80 extending along the second direction Y, and a plurality of low-voltage power supply lines 90 extending along the second direction Y, the first direction X intersects with the second direction Y. The first initial signal line 70 is configured to provide an initial voltage signal to the pixel drive circuit, the low-voltage power supply line 90 is configured to provide a low-power supply voltage signal to the cathode of the light emitting device, and the second initial signal line 80 is connected to the first initial signal line 70 such that the first initial signal lines 70 extending along the first direction X and the second initial signal lines 80 extending along the second direction Y constitute a net-like connecting structure.

In an exemplary implementation mode, the first initial signal line 70 may include a plurality of initial sub-lines 41 arranged at intervals along the first direction X. In at least one circuit unit, adjacent initial sub-lines 41 in the first direction X are connected to each other through initial connection electrodes 58 to form the first initial signal line 70 extending along the first direction X.

In an exemplary implementation mode, in at least one circuit unit, the second initial signal line 80 is connected to the initial connection electrode 58, and since the initial connection electrode 58 is connected to the initial sub-line 41, the connection between the second initial signal line 80 and the first initial signal line 70 is realized.

In an exemplary implementation mode, the drive circuit layer may include a plurality of conductive layers, and the initial sub-line 41, the initial connection electrode 58 and the second initial signal line 80 may be disposed in different conductive layers. In at least one circuit unit, the initial connection electrode 58 is connected to the initial sub-line 41 through a via, and the second initial signal line 80 is connected to the initial connection electrode 58 through a via.

In an exemplary implementation mode, the storage capacitor of the pixel drive circuit may include a first plate and a second plate, and the plurality of oxide transistors of the pixel drive circuit may include a first transistor T1, a second transistor T2, a third transistor T3, a fourth transistor T4, a fifth transistor T5, and a sixth transistor T6. In at least one circuit unit, a first electrode of the first transistor T1 is connected to the first initial signal line 70, and a second electrode of the first transistor T1 is connected to the second plate of the storage capacitor 50 and a second electrode of the sixth transistor T6. A first electrode of the second transistor T2 is connected to the first plate of the storage capacitor 50, a second electrode of the second transistor T2 is connected to the first electrode of the third transistor T3, a first electrode of the fourth transistor T4 is connected to the data signal line 63, a second electrode of the fourth transistor T4 is connected to a second electrode of the third transistor T3, a first electrode of the fifth transistor T5 is connected to the first power supply line 62, a second electrode of the fifth transistor T5 is connected to the first electrode of the third transistor T3, a first electrode of the sixth transistor T6 is connected to the second electrode of the third transistor T3, and a second electrode of the sixth transistor T6 is connected to the second electrode of the first transistor T1.

In an exemplary implementation mode, in at least one circuit unit, the first transistor T1, the fourth transistor T4, and the sixth transistor T6 may be located at a side of the storage capacitor 50 in the second direction Y, and the second transistor T2 and the fifth transistor T5 may be located at a side of the storage capacitor 50 in an opposite direction of the second direction Y.

In an exemplary implementation mode, in at least one circuit unit, the fourth transistor T4 may be located at a side of the storage capacitor 50 in the second direction Y, the sixth transistor T6 may be located at a side of the fourth transistor T4 away from the storage capacitor 50, the first transistor T1 may be located at a side of the sixth transistor T6 away from the storage capacitor 50, the second transistor T2 may be located at a side of the storage capacitor 50 in an opposite direction of the second direction Y, and the fifth transistor T5 may be located at a side of the second transistor T2 away from the storage capacitor 50.

In an exemplary implementation mode, the drive circuit layer may further include a first scan signal line 31, a second scan signal line 32, a third scan signal line 33, a first light emitting control line 34, and a second light emitting control line 35, and the first scan signal line 31, the second scan signal line 32, the third scan signal line 33, the first light emitting control line 34, and the second light emitting control line 35 may be in a shape of a straight line or a bending line extending along the first direction X.

In an exemplary implementation mode, the first transistor T1 to the sixth transistor T6 each includes a top gate electrode and a bottom gate electrode.

In an exemplary implementation mode, the first scan signal line 31 may be connected to the top gate electrode of the first transistor T1, and the first scan signal line 31 is configured to control the turn-on and turn-off of the first transistor T1. The second scan signal line 32 may be connected to the top gate electrode of the fourth transistor T4, and the second scan signal line 32 is configured to control the turn-on and turn-off of the fourth transistor T4. The third scan signal line 33 may be connected to the top gate electrode of the second transistor T2, and the third scan signal line 33 is configured to control the turn-on and turn-off of the second transistor T2. The first light emitting control line 34 may be connected to the top gate electrode of the sixth transistor T6, and the first light emitting control line 34 is configured to control the turn-on and turn-off of the sixth transistor T6. The second light emitting control line 35 may be connected to the top gate electrode of the fifth transistor T5. The second light emitting control line 35 is configured to control the turn-on and turn-off of the fifth transistor T5.

In an exemplary implementation mode, in at least one circuit unit, the second scan signal line 32 may be located at a side of the storage capacitor 50 in the second direction Y, the first light emitting control line 34 may be located at a side of the second scan signal line 32 away from the storage capacitor 50, and the first scan signal line 31 may be located at a side of the first light emitting control line 34 away from the storage capacitor 50. The third scan signal line 33 may be located at a side of the storage capacitor 50 in an opposite direction of the second direction Y, and the second light emitting control line 35 may be located at a side of the third scan signal line 33 away from the storage capacitor 50.

In an exemplary implementation mode, the first initial signal line 70 may be located at a side of the first scan signal line 31 away from the storage capacitor 50.

In an exemplary implementation mode, the plurality of unit columns may include at least a first unit column, a second unit column, and a third unit column, pixel drive circuits of a plurality of circuit units in the first unit column are connected to a red light emitting device that emits red light, pixel drive circuits of a plurality of circuit units in the second unit column are connected to a green light emitting device that emits green light, pixel drive circuits of a plurality of circuit units in the third unit column are connected to a blue light emitting device that emits blue light, the low-voltage power supply lines 90 may be disposed in the first unit column and the second unit column, and the second initial signal line 80 may be disposed in the third unit column. For example, the (n−1)-th column and n-th column may be the first unit column and the second unit column, respectively, the (n+1)-th column may be the third unit column, the low-voltage power supply lines 90 may be provided in the circuit units of the (n−1)-th column and n-th column, respectively, and the second initial signal line 80 may be provided in the circuit units of the (n+1)-th column.

In an exemplary implementation mode, the drive circuit layer may include at least a shielding conductive layer, a first insulation layer, a semiconductor layer, a second insulation layer, a first conductive layer, a third insulation layer, a second conductive layer, a fourth insulation layer, a third conductive layer, a fifth insulation layer, a first planarization layer, and a fourth conductive layer arranged sequentially in a direction away from the base substrate. The shielding conductive layer may include at least bottom gate electrodes of a plurality of oxide transistors, the semiconductor layer may include at least active layers of a plurality of oxide transistors, the first conductive layer may include at least the first plate of the storage capacitor 50 and top gate electrodes of a plurality of oxide transistors, the second conductive layer may at least include the second plate of the storage capacitor 50 and the first initial signal line 70, the third conductive layer may at least include first electrodes and second electrodes of a plurality of oxide transistors, and the fourth conductive layer may include at least a second initial signal line 80 and a low-voltage power supply line 90.

Exemplary description is made below through a preparation process of the display substrate of the exemplary embodiment. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition; coating may be any one or more of spray coating, spin coating, and ink-jet printing; and etching may be any one or more of dry etching and wet etching, which is not limited in present disclosure. A “thin film” refers to a layer of thin film made of a certain material on a substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a size of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

In an exemplary implementation mode, the preparation process of the display substrate may include following operations.

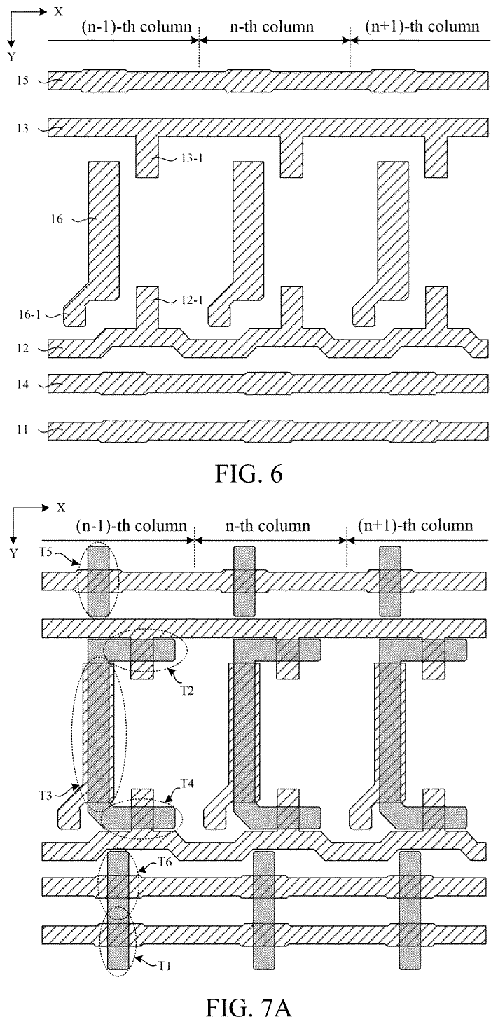

(1) A pattern of a shielding conductive layer is formed. In an exemplary implementation, forming the pattern of the shielding conductive layer may include: depositing a shielding thin film on a base substrate, and patterning the shielding thin film by a patterning process to form the pattern of the shielding conductive layer on the base substrate, as shown in FIG. 6.

In an exemplary implementation mode, the pattern of the shielding conductive layer may include at least a first shielding line 11, a second shielding line 12, a third shielding line 13, a fourth shielding line 14, a fifth shielding line 15, and a shielding electrode 16.

In an exemplary implementation, the first shielding line 11, the second shielding line 12, the third shielding line 13, the fourth shielding line 14, and the fifth shielding line 15 may be in a shape of a straight line or a bending line extending in a first direction X.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. In following description, “A extends in a B direction” means “a main body portion of A extends in a B direction”. In an exemplary implementation mode, the second direction Y may be a direction pointing to the bonding region from the display region, and an opposite direction of the second direction Y may be a direction pointing to the display region from the bonding region.

In an exemplary implementation mode, the first shielding line 11 may be located at a side of the shielding electrode 16 in the second direction Y. The first shielding line 11 is configured to shield the first transistor T1, reduce the influence of light on the electrical characteristics of the first transistor T1, and is also configured as a bottom gate electrode of the first transistor T1.

In an exemplary implementation mode, the second shielding line 12 may be located at a side of the shielding electrode 16 in the second direction Y and between the shielding electrode 16 and the first shielding line 11. A fourth bottom gate electrode 12-1 is provided at a side of the second shielding line 12 close to the shielding electrode 16. The fourth bottom gate electrode 12-1 is configured to shield the fourth transistor T4, reduce the influence of light on the electrical characteristics of the fourth transistor T4, and is also configured as a bottom gate electrode of the fourth transistor T4.

In an exemplary implementation mode, the third shielding line 13 may be located at a side of the shielding electrode 16 in an opposite direction of the second direction Y so that the shielding electrode 16 is located between the second shielding line 12 and the third shielding line 13. A side of the third shielding line 13 close to the shielding electrode 16 is provided with a second bottom gate electrode 13-1, the second bottom gate electrode 13-1 is configured to shield the second transistor T2, reduce the influence of light on the electrical characteristics of the second transistor T2, and is also configured as a bottom gate electrode of the second transistor T2.

In an exemplary implementation mode, the fourth shielding line 14 may be located between the first shielding line 11 and the second shielding line 12. The fourth shielding line 14 is configured to shield the sixth transistor T6 to reduce the influence of light on the electrical characteristics of the sixth transistor T6, and is also configured as a bottom gate electrode of the sixth transistor T6.

In an exemplary implementation mode, the fifth shielding line 15 may be located at a side of the third shielding line 13 away from the shielding electrode 16. The fifth shielding line 15 is configured to shield the fifth transistor T5, reduce the influence of light on the electrical characteristics of the fifth transistor T5, and is also configured as a bottom gate electrode of the fifth transistor T5.

In an exemplary implementation mode, the shielding electrode 16 may have a shape of a strip extending along the second direction Y. The shielding electrode 16 is configured to shield the third transistor T3, reduce the influence of light on the electrical characteristics of the third transistor T3, and is also configured as a bottom gate electrode of the third transistor T3.

In an exemplary implementation mode, an end of the shielding electrode 16 close to the first shielding line 11 is provided with a shielding connection block 16-1 configured to be connected with a subsequently formed fifth connection electrode.

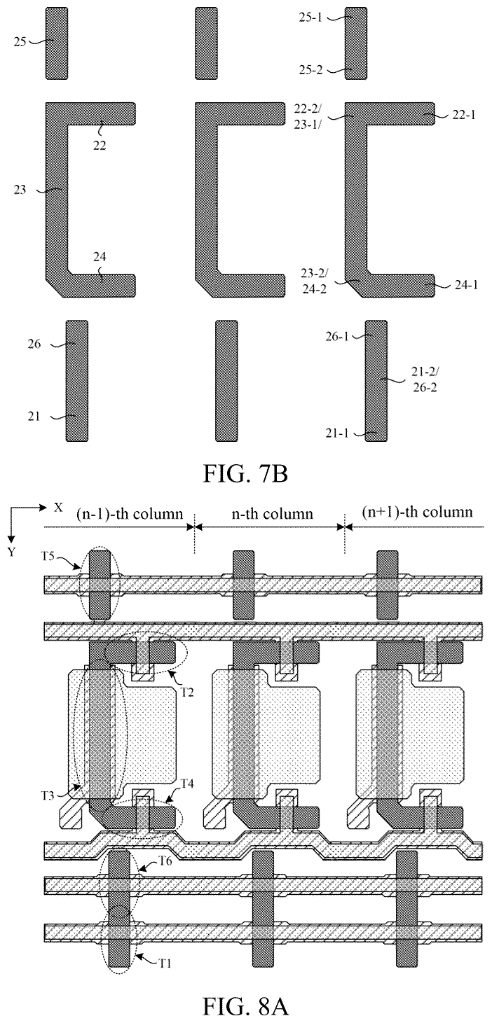

(2) A pattern of a semiconductor layer is formed. In an exemplary implementation mode, forming a pattern of a semiconductor layer may include sequentially depositing a first insulation thin film and a semiconductor thin film on a base substrate, patterning the semiconductor thin film by a patterning process to form a first insulation layer covering the shielding conductive layer, and a pattern of a semiconductor layer disposed on the first insulation layer, as shown in FIGS. 7A and 7B, FIG. 7B is a schematic plan view of the semiconductor layer in FIG. 7A.

In an exemplary implementation mode, the pattern of the semiconductor layer may include a first active layer 21 of the first transistor T1 to a sixth active layer 26 of the sixth transistor T6, and the second active layer 22, the third active layer 23, and the fourth active layer 24 are of an interconnected integral structure, and the first active layer 21 and the sixth active layer 26 are of an interconnected integral structure.

In an exemplary implementation mode, in the second direction Y, the first active layer 21, the fourth active layer 24, and the sixth active layer 26 may be located at a side of the third active layer 23 in the second direction Y, and the second active layer 22 and the fifth active layer 25 may be located at a side of the third active layer 23 in an opposite direction of the second direction Y.

In an exemplary implementation mode, the first active layers 21 to the sixth active layers 26 may be in an “I” shape. The second active layer 22 and the fourth active layer 24 may have a shape of a strip extending along the first direction X, and the third active layer 23 may have a shape of a strip extending along the second direction Y. A first end of the second active layer 22 is connected to one end of the third active layer 23, a second end of the second active layer 22 extends along the first direction X, a first end of the fourth active layer 24 is connected to the other end of the third active layer 23, and a second end of the fourth active layer 24 extends along the first direction X, so that the second active layer 22, the third active layer 23 and the fourth active layer 24 of an integral structure form a “C” shape.

In an exemplary implementation mode, an orthographic projection of the third active layer 23 on the base substrate may be within the range of an orthographic projection of the shielding electrode 16 on the base substrate, so that the channel region of the third transistor T3 may be effectively shielded by the shielding electrode 16.

In an exemplary implementation mode, an active layer of each transistor may include a first region, a second region, and a channel region located between the first region and the second region. In an exemplary implementation mode, a second region 21-2 of the first active layer 21 and a second region 26-2 of the sixth active layer 26 are of an interconnected integral structure, i.e., the second region 21-2 of the first active layer 21 may serve as the second region 26-2 of the sixth active layer 26. A second region 22-2 of the second active layer 22 and a first region 23-1 of the third active layer 23 are of an interconnected integral structure, that is, the second region 22-2 of the second active layer 22 can serve as the first region 23-1 of the third active layer 23. A second region 24-2 of the fourth active layer 24 and a second region 23-2 of the third active layer 23 are of an interconnected integral structure, that is, the second region 24-2 of the fourth active layer 24 can serve as the first region 23-1 of the third active layer 23. A first region 21-1 of the first active layer 21, a first region 22-1 of the second active layer 22, a first region 24-1 of the fourth active layer 24, a first region 25-1 of the fifth active layer 25, a second region 25-2 of the fifth active layer 25, and a first region 26-1 of the sixth active layer 26 may be individually provided.

In an exemplary implementation, the semiconductor layer may be made of an oxide, and the first transistor T1 to the sixth transistor T6 are all oxide transistors. In an exemplary implementation mode, the semiconductor thin film may be made of indium gallium zinc oxide (IGZO) with a high electron mobility. The thickness of the semiconductor layer may be about 20 nm to 40 nm. For example, the thickness of the semiconductor layer may be about 30 nm.

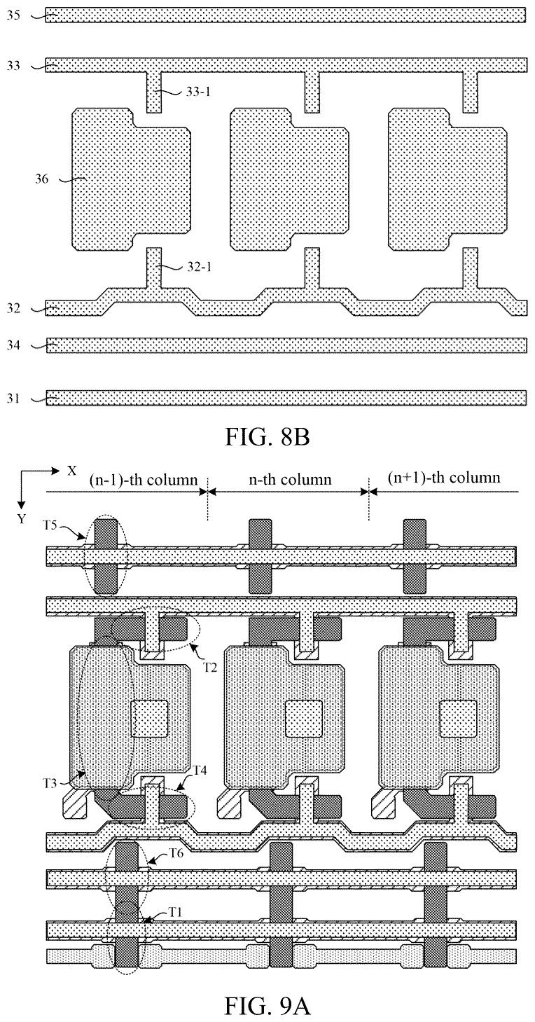

(3) A pattern of a first conductive layer is formed. In an exemplary implementation, forming the pattern of the first conductive layer may include: depositing sequentially a second insulation thin film and a first conductive thin film on the base substrate on which the aforementioned patterns are formed, and patterning the first conductive thin film through a patterning process to form a second insulation layer that covers a pattern of the semiconductor layer and form the pattern of the first conductive layer arranged on the second insulation layer, as shown in FIG. 8A and FIG. 8B, and FIG. 8B is a planar schematic diagram of the first conductive layer in FIG. 8A. In an exemplary implementation mode, the first conductive layer may be referred to as a first gate metal (GATE1) layer.

In an exemplary implementation mode, the pattern of the first conductive layer includes at least a first scan signal line 31, a second scan signal line 32, a third scan signal line 33, a first light emitting control line 34, a second light emitting control line 35, and a first plate 36 of the storage capacitor.

In an exemplary implementation mode, the first plate 36 may be in a shape of a rectangle, and a chamfer may be provided at a corner of the rectangle. An orthographic projection of the first plate 36 on the base substrate is at least partially overlapped with an orthographic projection of the third active layer of the third transistor T3 on the base substrate. In an exemplary implementation mode, the first plate 36 may simultaneously serve as a plate of the storage capacitor and a top gate electrode of the third transistor T3 (the drive transistor), that is, the top gate electrode of the third transistor T3 and the first plate 36 of the storage capacitor are of an integral structure.

In an exemplary implementation mode, the first scan signal line 31, the second scan signal line 32, the third scan signal line 33, the first light emitting control line 34, and the second light emitting control line 35 may be in a shape of a straight line or a bending line extending in a first direction X.

In an exemplary implementation mode, the first scan signal line 31 may be located at a side of the first plate 36 in the second direction Y, and a region where the first scan signal line 31 overlaps with the first active layer serves as the top gate electrode of the first transistor T1, i.e., the first scan signal line 31 and the top gate electrode of the first transistor T1 are of an interconnected integral structure.

In an exemplary implementation, an orthographic projection of the first scan signal line 31 on the base substrate may be within a range of an orthographic projection of the first shielding line 11 on the base substrate, so that a channel region of the first transistor T1 may be effectively shielded by the first shielding line 11.

In an exemplary implementation mode, the second scan signal line 32 may be located at a side of the first plate 36 in the second direction Y and between the first plate 36 and the first scan signal line 31. A side of the second scan signal line 32 close to the first plate 36 is connected with a fourth top gate electrode 32-1, an orthographic projection of the fourth top gate electrode 32-1 on the base substrate overlaps at least partially with an orthographic projection of the fourth active layer on the base substrate, and the fourth top gate electrode 32-1 is configured as the top gate electrode of the fourth transistor T4.

In an exemplary implementation mode, an orthographic projection of the second scan signal line 32 on the base substrate may be within the range of an orthographic projection of the second shielding line 12 on the base substrate, and an orthographic projection of the fourth top gate electrode 32-1 on the base substrate may be within the range of an orthographic projection of the fourth bottom gate electrode 12-1 on the base substrate, so that the channel region of the fourth transistor T4 may be effectively shielded by the fourth bottom gate electrode 12-1.

In an exemplary implementation mode, the third scan signal line 33 may be located at a side of the first plate 36 in an opposite direction of the second direction Y so that the first plate 36 is located between the second scan signal line 32 and the third scan signal line 33. A side of the third scan signal line 33 close to the first plate 36 is connected with a second top gate electrode 33-1, an orthographic projection of the second top gate electrode 33-1 on the base substrate overlaps at least partially with an orthographic projection of the second active layer on the base substrate, and the second top gate electrode 33-1 is configured as the top gate electrode of the second transistor T2.

In an exemplary implementation mode, an orthographic projection of the third scan signal line 33 on the base substrate may be within the range of an orthographic projection of the third shielding line 13 on the base substrate, and an orthographic projection of the second top gate electrode 33-1 on the base substrate may be within the range of an orthographic projection of the second bottom gate electrode 13-1 on the base substrate, so that the channel region of the second transistor T2 may be effectively shielded by the second bottom gate electrode 13-1.

In an exemplary implementation mode, the first scan signal line 31 and the third scan signal line 33 may transmit a same scan signal and the first scan signal line 31 and the third scan signal line 33 are connected to a same scan signal source.

In an exemplary implementation mode, the first light emitting control line 34 may be located at a side of the second scan signal line 32 away from the first plate 36, and may be located between the first scan signal line 31 and the second scan signal line 32, and a region where the first light emitting control line 34 overlaps with the sixth active layer serves as a top gate electrode of the sixth transistor T6, that is, the first light emitting control line 34 and the top gate electrode of the sixth transistor T6 are of an interconnected integral structure.

In an exemplary implementation mode, an orthographic projection of the first light emitting control line 34 on the base substrate may be within the range of an orthographic projection of the fourth shielding line 14 on the base substrate, so that the channel region of the sixth transistor T6 may be effectively shielded by the fourth shielding line 14.

In an exemplary implementation mode, the second light emitting control line 35 may be located at a side of the third scan signal line 33 away from the first plate 36, and a region where the second light emitting control line 35 overlaps with the fifth active layer serves as a top gate electrode of the fifth transistor T5, that is, the second light emitting control line 35 and the top gate electrode of the fifth transistor T5 are of an interconnected integral structure.

In an exemplary implementation mode, an orthographic projection of the second light emitting control line 35 on the base substrate may be within the range of an orthographic projection of the fifth shielding line 15 on the base substrate, so that the channel region of the fifth transistor T5 may be effectively shielded by the fifth shielding line 15.

In an exemplary implementation, after the pattern of the first conductive layer is formed, the semiconductor layer may be subjected to a conductive treatment by using the first conductive layer as a shield. A region of the semiconductor layer, which is shielded by the first conductive layer, forms channel regions of the first transistor T1 to the sixth transistor T6, and a region of the semiconductor layer, which is not shielded by the first conductive layer, is made be conductive, that is, first regions and second regions of the first transistor T1 to the sixth active layer are all made be conductive.

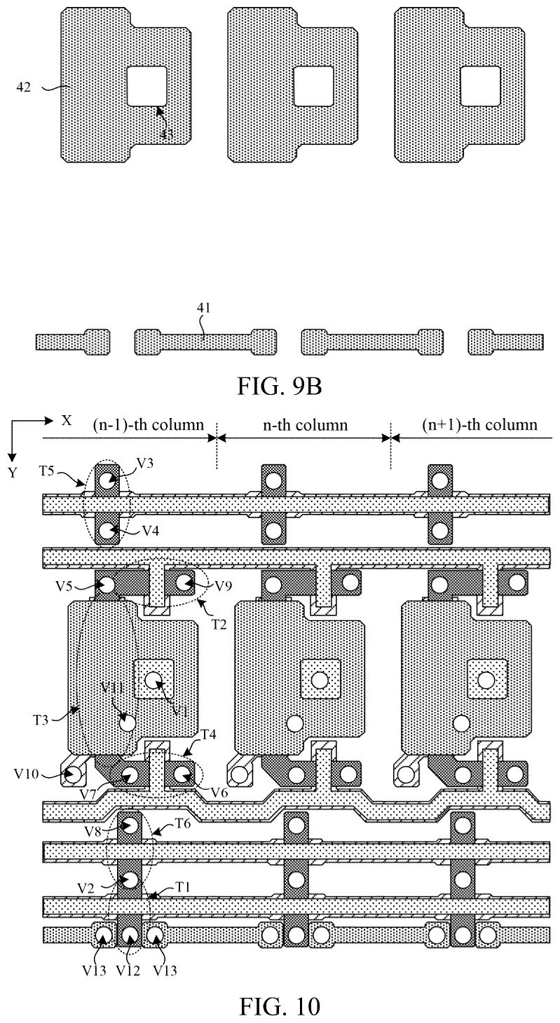

(4) A pattern of a second conductive layer is formed. In an exemplary implementation, forming a pattern of a second conductive layer may include: a third insulation thin film and a second conductive thin film are sequentially deposited on the base substrate on which the aforementioned patterns are formed, and the second conductive thin film is patterned through a patterning process to form a third insulation layer that covers the first conductive layer and the pattern of the second conductive layer arranged on the third insulation layer, as shown in FIG. 9A and FIG. 9B. FIG. 9B is a schematic plan view of the second conductive layer in FIG. 9A. In an exemplary implementation mode, the second conductive layer may be referred to as a second gate metal (GATE2) layer.

In an exemplary implementation mode, the pattern of the second conductive layer of each circuit unit includes at least an initial sub-line 41 and a second plate 42 of the storage capacitor.

In an exemplary implementation mode, a profile of second plate 42 may be in a shape of a rectangle, a chamfer may be provided at a corner of the rectangle, an orthographic projection of the second plate 42 on the base substrate is at least overlapped with an orthographic projection of the first plate 36 on the base substrate, the second plate 42 may serve as anther plate of the storage capacitor, and the first plate 36 and the second plate 42 constitute the storage capacitor of the pixel drive circuit.

In an exemplary implementation mode, the second plate 42 is provided with an opening 43 which may have a rectangular shape and may be located in the middle of the second plate 42, so that the second plate 42 forms an annular structure. The opening 43 exposes the third insulation layer covering the first plate 36, and an orthographic projection of the first plate 36 on the base substrate contains an orthographic projection of the opening 43 on the base substrate. In an exemplary implementation mode, the opening 43 is configured to accommodate a first via formed subsequently, and the first via is located in the opening 43 and exposes the first plate 36, so that a second electrode of the first transistor T1 formed subsequently is connected with the first plate 36.

In an exemplary implementation, the initial sub-line 41 may be in a shape of a line in which a main portion extends in the first direction X. In the first direction X, the initial sub-line 41 may be arranged between the first regions of the first active layers of adjacent circuit units in the first direction X. In the second direction Y, the initial sub-line 41 may be located at a side of the first scan signal line 31 away from the second plate 42. The initial sub-line 41 is configured to form a first initial signal line that transmits an initial voltage signal and extends in the first direction X using a subsequently formed initial connection electrode.

(5) A pattern of a fourth insulation layer is formed. In an exemplary implementation, forming a pattern of a fourth insulation layer may include: depositing a fourth insulating thin film on the base substrate on which the aforementioned patterns are formed, and patterning the fourth insulating thin film by a patterning process, to form a fourth insulation layer covering the second conductive layer, wherein a plurality of vias are provided on the fourth insulation layer, as shown in FIG. 10.

In an exemplary implementation mode, the plurality of vias include at least a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, and a thirteenth via V13.

In an exemplary implementation mode, an orthographic projection of the first via V1 on the base substrate is located within a range of an orthographic projection of the opening 43 on the base substrate, the fourth insulation layer and the third insulation layer within the first via V1 are etched away to expose a surface of the first plate 36, and the first via V1 is configured such that the second electrode of the first transistor T1 formed subsequently is connected with the first plate 36 through the via.

In an exemplary implementation mode, an orthographic projection of the second via V2 on the base substrate is within an orthographic projection of the second region of the first active layer (also the second region of the sixth active layer) on the base substrate, the fourth insulation layer, the third insulation layer and the second insulation layer within the second via V2 are etched away to expose the surface of the second region of the first active layer, and the second via V2 is configured such that the second electrode of the first transistor T1 formed subsequently (also the second electrode of the sixth transistor T6) is connected to the second region of the first active layer (also the second region of the sixth active layer) through the via.

In an exemplary implementation mode, an orthographic projection of the third via V3 on the base substrate is located within a range of an orthographic projection of a first region of the fifth active layer on the base substrate, the fourth insulation layer, the third insulation layer, and the second insulation layer within the third via V3 are etched away to expose a surface of the first region of the fifth active layer, and the third via V3 is configured such that the first electrode of the fifth transistor T5 formed subsequently is connected with the first region of the fifth active layer through the via.

In an exemplary implementation mode, an orthographic projection of the fourth via V4 on the base substrate is within the range of an orthographic projection of the second region of the fifth active layer on the base substrate, the fourth insulation layer, the third insulation layer and the second insulation layer within the fourth via V4 are etched away to expose the surface of the second region of the fifth active layer, the fourth via V4 is configured such that the second electrode of the fifth transistor T5 formed subsequently is connected to the second region of the fifth active layer through the via.

In an exemplary implementation mode, an orthographic projection of the fifth via V5 on the base substrate is within an orthographic projection of the second region of the second active layer (also the first region of the third active layer) on the base substrate, the fourth insulation layer, the third insulation layer and the second insulation layer within the fifth via V5 are etched away to expose the surface of the second region of the second active layer, and the fifth via V5 is configured such that the second electrode of the second transistor T2 formed subsequently (also the first electrode of the third transistor T3) is connected to the second region of the second region of the second active layer (also the first region of the third active layer) through the via.

In an exemplary implementation mode, an orthographic projection of the sixth via V6 on the base substrate is within the range of an orthographic projection of the first region of the fourth active layer on the base substrate, the fourth insulation layer, the third insulation layer and the second insulation layer within the sixth via V6 are etched away to expose the surface of the first region of the fourth active layer, and the sixth via V6 is configured such that the first electrode of the fourth transistor T4 formed subsequently is connected to the first region of the fourth active layer through the via.

In an exemplary implementation mode, an orthographic projection of the seventh via V7 on the base substrate is within an orthographic projection of the second region of the fourth active layer (also the second region of the third active layer) on the base substrate, the fourth insulation layer, the third insulation layer and the second insulation layer within the seventh via V7 are etched away to expose the surface of the second region of the fourth active layer, and the seventh via V7 is configured such that the second electrode of the fourth transistor T4 formed subsequently (also the second electrode of the third transistor T3) is connected to the second region of the fourth active layer (also the second region of the third active layer) through the via.

In an exemplary implementation mode, an orthographic projection of the eighth via V8 on the base substrate is within the range of an orthographic projection of the first region of the sixth active layer on the base substrate, the fourth insulation layer, the third insulation layer and the second insulation layer within the eighth via V8 are etched away to expose the surface of the first region of the sixth active layer, and the eighth via V8 is configured such that the first electrode of the sixth transistor T6 formed subsequently is connected to the first region of the sixth active layer through the via.

In an exemplary implementation mode, an orthographic projection of the ninth via V9 on the base substrate is within the range of an orthographic projection of the first region of the second active layer on the base substrate, the fourth insulation layer, the third insulation layer and the second insulation layer in the ninth via V9 are etched away to expose the surface of the first region of the second active layer, and the ninth via V9 is configured such that the first electrode of the second transistor T2 formed subsequently is connected to the first region of the second active layer through the via.

In an exemplary implementation mode, an orthographic projection of the tenth via V10 on the base substrate is within the range of an orthographic projection of the shielding connection block 16-1 of the shielding electrode 16 on the base substrate, the fourth insulation layer, the third insulation layer, the second insulation layer and the first insulation layer in the tenth via V10 are etched away to expose the surface of the shielding connection block 16-1, and the tenth via V10 is configured such that the subsequently formed fifth connection electrode is connected to the shielding electrode 16 through the via.

In an exemplary implementation mode, an orthographic projection of the eleventh via V11 on the base substrate is within the range of an orthographic projection of the second plate 42 on the base substrate, the fourth insulation layer in the eleventh via V11 is etched away to expose the surface of the second plate 42, and the eleventh via V11 is configured such that the subsequently formed seventh connection electrode is connected to the second plate 42 through the via.

In an exemplary implementation mode, an orthographic projection of the twelfth via V12 on the base substrate is within the range of an orthographic projection of the first region of the first active layer on the base substrate, the fourth insulation layer, the third insulation layer and the second insulation layer in the twelfth via V12 are etched away to expose the surface of the first region of the first active layer, and the twelfth via V12 is configured such that the first electrode of the first transistor T1 formed subsequently is connected to the first region of the first active layer through the via.

In an exemplary implementation mode, an orthographic projection of the thirteenth via V13 on the base substrate is within the range of an orthographic projection of an end of the initial sub-line 41 close to the first region of the first active layer on the base substrate, the fourth insulation layer in the thirteenth via V13 is etched away to expose the surface of an end of the initial sub-line 41, and the thirteenth via V13 is configured such that the first electrode of the first transistor T1 formed subsequently is connected to the initial sub-line 41 through the via.

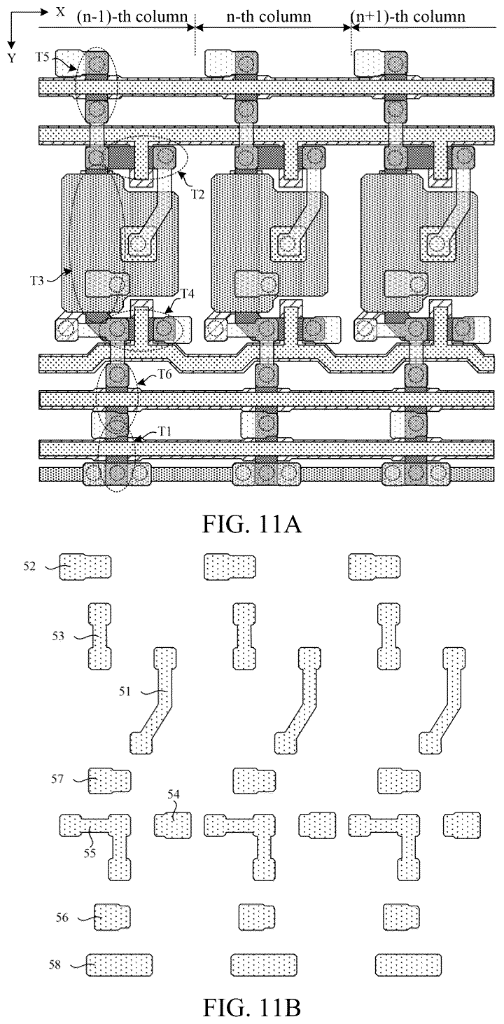

(6) A pattern of a third conductive layer is formed. In an exemplary implementation, forming the third conductive layer may include: depositing a third conductive thin film on the base substrate on which the aforementioned patterns are formed, and patterning the third conductive thin film by a patterning process to form the third conductive layer arranged on the fourth insulation layer, as shown in FIG. 11A and FIG. 11B, FIG. 11B being a planar schematic diagram of the third conductive layer in FIG. 11A. In an exemplary implementation mode, the third conductive layer may be referred to as a first source-drain metal (SD1) layer.

In an exemplary implementation mode, the third conductive layer of each circuit unit includes at least a first connection electrode 51, a second connection electrode 52, a third connection electrode 53, a fourth connection electrode 54, a fifth connection electrode 55, a sixth connection electrode 56, a seventh connection electrode 57, and an initial connection electrode 58.

In an exemplary implementation mode, the first connection electrode 51 may be shaped as a bending line with a main body portion extending in the second direction Y, a first end of the first connection electrode 51 is connected to the first plate 36 through the first via V1, and a second end of the first connection electrode 51 is connected to the first region of the second active layer through the ninth via V9, so that the first plate 36 and the first electrode of the second transistor T2 have the same potential. In an exemplary implementation mode, the first connection electrode 51 may serve as the first electrode of the second transistor T2 (i.e., the first node N1 of the pixel drive circuit).

In an exemplary implementation, the second connection electrode 52 may be in a shape of a polygon, and the second connection electrode 52 is connected to the first region of the fifth active layer through the third via V3. In an exemplary implementation mode, the second connection electrode 52 may serve as the first electrode of the fifth transistor T5 and the second connection electrode 52 is configured to be connected to a first power supply line formed subsequently.

In an exemplary implementation, the third connection electrode 53 may be in a shape of a strip in which a main portion extends in the second direction Y, a first end of the third connection electrode 53 is connected to the second region of the fifth active layer through the fourth via V4, and a second end of the third connection electrode 53 is connected to the second region of the second active layer through the fifth via V5. In an exemplary implementation mode, the third connection electrode 53 may simultaneously serve as the second electrode of the second transistor T2, the first electrode of the third transistor T3, and the second electrode of the fifth transistor T5 (i.e., the second node N2 of the pixel drive circuit).

In an exemplary implementation mode, the fourth connection electrode 54 may be in a shape of a polygon and the fourth connection electrode 54 is connected to the first region of the fourth active layer through the sixth via V6. In an exemplary implementation mode, the fourth connection electrode 54 may serve as a first electrode of the fourth transistor T4 and the fourth connection electrode 54 is configured to be connected to the data signal line formed subsequently.

In an exemplary implementation mode, the fifth connection electrode 55 may be in a “L” shape, a first end of the fifth connection electrode 55 is connected to the first region of the sixth active layer through the eighth via V8, a second end of the fifth connection electrode 55 is connected to the shielding connection block 16-1 of the shielding electrode 16 through the tenth via V10, a third end of the fifth connection electrode 55 is connected to the second region of the fourth active layer through the seventh via V7, and the third end of the fifth connection electrode 55 is located between the first end and the second end. In an exemplary implementation mode, the fifth connection electrode 55 may simultaneously serve as the second electrode of the third transistor T3, the second electrode of the fourth transistor T4, and the first electrode of the sixth transistor T6 (i.e., the third node N3 of the pixel drive circuit). Since the shielding electrode 16 serves as the bottom gate electrode of the third transistor T3, connection of the bottom gate electrode of the third transistor T3 to the second electrode of the fourth transistor T4 and the first electrode of the sixth transistor T6 through the fifth connection electrode 55 is realized.

In an exemplary implementation mode, the sixth connection electrode 56 may be in a shape of a polygon, and the sixth connection electrode 56 is connected to the second region of the first active layer (also the second region of the sixth active layer) through the second via V2. In an exemplary implementation mode, the sixth connection electrode 56 may simultaneously serve as the second electrode of the first transistor T1 and the second electrode of the sixth transistor T6, and the sixth connection electrode 56 is configured to be connected with the anode connection electrode formed subsequently.

In an exemplary implementation, the seventh connection electrode 57 may be in a shape of a polygon, and the seventh connection electrode 57 is connected to the second plate 42 through the eleventh via V11. In an exemplary implementation mode, the seventh connection electrode 57 is configured to be connected to the anode connection electrode formed subsequently.

In an exemplary implementation mode, the initial connection electrode 58 may have a shape of a strip with a main body portion extending along the first direction X, the middle part of the initial connection electrode 58 is connected to the first region of the first active layer through the twelfth via V12, and two ends of the initial connection electrode 58 are respectively connected to the ends of adjacent initial sub-lines 41 through the thirteenth via V13. On the one hand, an interconnection between the plurality of initial sub-lines 41 is realized to form the first initial signal line, and on the other hand, a connection between the first initial signal line and the first electrode of the first transistor T1 is realized, so that an initial voltage transmitted by the first initial signal line is written to the first electrode of the first transistor T1.

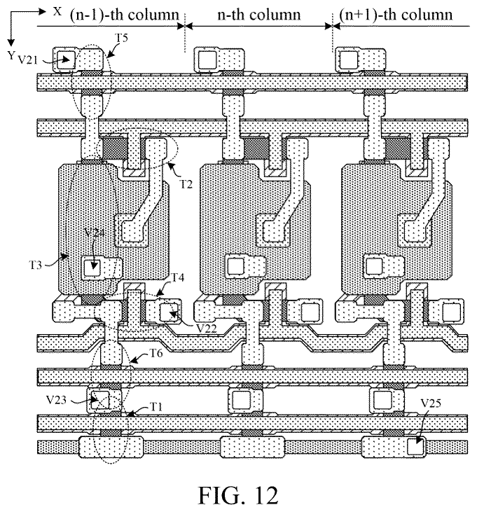

(7) A pattern of a first planarization layer is formed. In an exemplary implementation, forming the pattern of the first planarization layer may include: first depositing a fifth insulating thin film on the base substrate on which the aforementioned patterns are formed, then coating a first planarization thin film, and patterning the first planarization thin film and the fifth insulating thin film by a patterning process to form a fifth insulation layer that covers the pattern of the third conductive layer and the first planarization layer arranged on the fifth insulation layer, the first planarization layer being provided with a plurality of vias, as shown in FIG. 12.

In an exemplary implementation mode, the plurality of vias in each circuit unit include at least a twenty-first via V21, a twenty-second via V22, a twenty-third via V23, and a twenty-fourth via V24.

In an exemplary implementation, an orthographic projection of the twenty-first via V21 on the base substrate is within a range of an orthographic projection of the second connection electrode 52 on the base substrate, the first planarization layer and the fifth insulation layer within the twenty-first via V21 are etched away to expose a surface of the second connection electrode 52, and the twenty-first via V21 is configured such that a first power supply line formed subsequently is connected to the second connection electrode 52 through this via.

In an exemplary implementation, an orthographic projection of the twenty-second via V22 on the base substrate is within a range of an orthographic projection of the fourth connection electrode 54 on the base substrate, the first planarization layer and the fifth insulation layer within the twenty-second via V22 are etched away to expose a surface of the fourth connection electrode 54, and the twenty-second via V22 is configured such that a data signal line formed subsequently is connected to the fourth connection electrode 54 through this via.

In an exemplary implementation, an orthographic projection of the twenty-third via V23 on the base substrate is within a range of an orthographic projection of the sixth connection electrode 56 on the base substrate, the first planarization layer and the fifth insulation layer within the twenty-third via V23 are etched away to expose a surface of the sixth connection electrode 56, and the twenty-third via V23 is configured such that an anode connection electrode formed subsequently is connected to the sixth connection electrode 56 through this via.

In an exemplary implementation, an orthographic projection of the twenty-fourth via 24 on the base substrate is within a range of an orthographic projection of the seventh connection electrode 57 on the base substrate, the first planarization layer and the fifth insulation layer within the twenty-fourth via V24 are etched away to expose a surface of the seventh connection electrode 57, and the twenty-fourth via V24 is configured such that the anode connection electrode formed subsequently is connected to the seventh connection electrode 57 through this via.

In an exemplary implementation mode, some circuit units further include a twenty-fifth via V25, an orthographic projection of the twenty-fifth via V25 on the base substrate overlaps at least partially with an orthographic projection of the initial connection electrode 58 on the base substrate, the first planarization layer and the fifth insulation layer within the twenty-fifth via V25 are etched away to expose the surface of the initial connection electrode 58, and the twenty-fifth via V25 is configured such that a subsequently formed second initial signal line is connected to the initial connection electrode 58 through the via.

In an exemplary implementation mode, the twenty-fifth Via V25 may be provided in the circuit units of the (n+1)-th column, i.e., the circuit units of the (n+1)-th column are provided with the second initial signal line, while the circuit units of the (n−1)-th column and the n-th column are not provided with the twenty-fifth via V25.

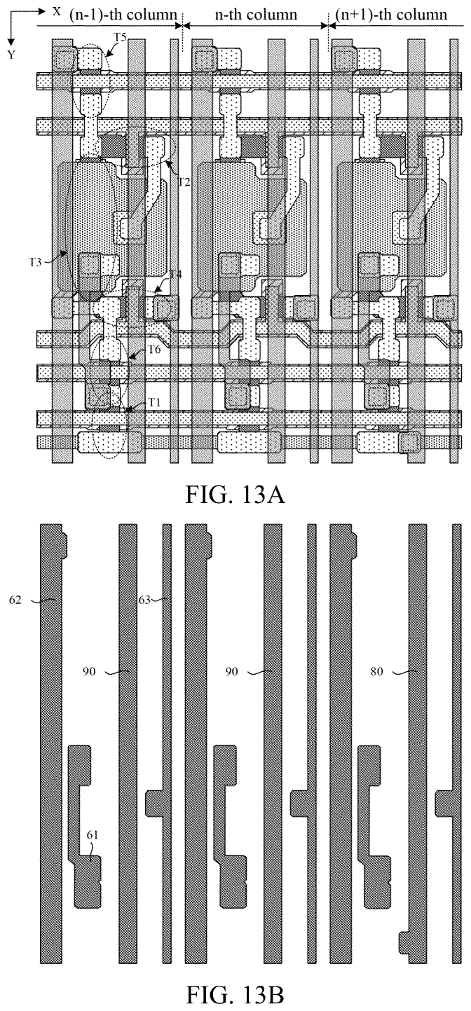

(8) A pattern of a fourth conductive layer is formed. In an exemplary implementation, forming the pattern of the fourth conductive layer may include: depositing a fourth conductive thin film on the base substrate on which the aforementioned patterns are formed, and patterning the fourth conductive thin film by a patterning process to form the fourth conductive layer arranged on the first planarization layer, as shown in FIG. 13A and FIG. 13B, FIG. 13B being a planar schematic diagram of the fourth conductive layer in FIG. 13A. In an exemplary implementation mode, the fourth conductive layer may be referred to as a second source-drain metal (SD2) layer.

In an exemplary implementation mode, the fourth conductive layer of each circuit unit includes at least an anode connection electrode 61, a first power supply line 62 and a data signal line 63.

In an exemplary implementation, the anode connection electrode 61 may be in a shape of a bending line in which a main portion extends in the second direction Y, a first end of the anode connection electrode 61 is connected to the sixth connection electrode 56 through the twenty-third via V23, and a second end of the anode connection electrode 61 is connected to the seventh connection electrode 57 through the twenty-fourth via V24. Since the sixth connection electrode 56 is connected to the second region of the sixth active layer (also the second region of the first active layer) through a via, and the seventh connection electrode 57 is connected to the second plate 42 through a via, it is realized that the second plate 42, the second electrode of the first transistor T1 and the second electrode of the sixth transistor T6 have the same potential (i.e., the fourth node N4 of the pixel drive circuit). In an exemplary implementation, the anode connection electrode 61 is configured to be connected to an anode formed subsequently, thereby enabling the pixel drive circuit to output a drive current to a light emitting device.

In an exemplary implementation, the first power supply line 62 may be in a shape of a straight line or a bending line in which a main portion extends in the second direction Y, and the first power supply line 62 is connected to the second connection electrode 52 through the twenty-first via V21. Since the second connection electrode 52 is connected to the first region of the fifth active layer through a via, it is realized that the first power supply line 62 can write a constant first voltage signal to the first electrode of the fifth transistor T5.

In an exemplary implementation, the data signal line 63 may be in a shape of a straight line in which a main portion extends in the second direction Y, and the data signal line 63 is connected to the fourth connection electrode 54 through the twenty-second via V22. Since the fourth connection electrode 54 is connected with the first region of the fourth active layer through a via, it is achieved that the data signal line 63 can write a data signal into the first electrode of the fourth transistor T4.

In an exemplary implementation mode, the fourth conductive layer of some circuit units may also include a second initial signal line 80. The shape of the second initial signal line 80 may be in a shape of a straight line or a bending line in which a main portion extends in the second direction Y, and the second initial signal line 80 is connected to the initial connection electrode 58 through the twenty-fifth via V25. Since the initial sub-line 41 forms a first initial signal line extending along the first direction X through the initial connection electrode 58, and the second initial signal line 80 is connected with the initial connection electrode 58, so that the first initial signal line extending along the first direction X and the second initial signal line 80 extending along the second direction Y form initial signal lines of the net-like connecting structure in the display region, the resistance of the initial signal line can be reduced to the maximum extent, the voltage drop of the initial voltage can be reduced, and the uniformity of the initial voltage in the display substrate can be effectively improved, the display uniformity can be effectively improved, and the display attribute and the display quality can be improved.

In an exemplary implementation mode, the fourth conductive layer of some circuit units may also include a low-voltage power supply line (a second power supply line) 90. The low-voltage power supply line 90 may be in a shape of a straight line or a bending line in which a main portion extends in the second direction Y and may be located between the first power supply line 62 and the data signal line 63. The low-voltage power supply line 90 is configured to output a constant second voltage signal to the cathode of the light emitting device.

In some exemplary implementation modes, the plurality of unit columns of the display panel may include at least a first unit column, a second unit column, and a third unit column, pixel drive circuits of a plurality of circuit units in the first unit column are connected to a red light emitting device that emits red light, pixel drive circuits of a plurality of circuit units in the second unit column are connected to a green light emitting device that emits green light, pixel drive circuits of a plurality of circuit units in the third unit column are connected to a blue light emitting device that emits blue light. For example, the (n−1)-th column may be a first unit column, the n-th column may be a second unit column, the (n+1)-th column may be a third unit column, the low-voltage power supply lines 90 may be provided in circuit units in the (n−1)-th column and the n-th column, and the second initial signal lines 80 may be provided in circuit units in the (n+1)-th column.

In some possible exemplary implementation modes, the second initial signal line 80 may be disposed in the circuit units of the n-th column and (n+1)-th column, and the low-voltage power supply line 90 may be disposed in the circuit units of the (n−1)-th column, which is not limited here in the present disclosure.

Subsequently, a second planarization thin film is coated on the base substrate on which the aforementioned patterns are formed, and the second planarization thin film is patterned by a patterning process to form a second planarization layer that covers the pattern of the fourth conductive layer. The second planarization layer is provided with an anode via, an orthographic projection of the anode via on the base substrate is within a range of the orthographic projection of the anode connection electrode on the base substrate, and the anode via is configured such that the anode formed subsequently is connected to the anode connection electrode through this via.

So far, the drive circuit layer has been prepared on the base substrate. In a plane parallel to the display substrate, the drive circuit layer may include a plurality of circuit units, each of which may include a pixel drive circuit, and a first scan signal line, a second scan signal line, a third scan signal line, a first light emitting control line, a second light emitting control line, a first initial signal line, a first power supply line, and a data signal line connected to the pixel drive circuit. In a plane perpendicular to the display substrate, the drive circuit layer may include a shielding conductive layer, a first insulation layer, a semiconductor layer, a second insulation layer, a first conductive layer, a third insulation layer, a second conductive layer, a fourth insulation layer, a third conductive layer, a fifth insulation layer, a first planarization layer, a fourth conductive layer and a second planarization layer which are arranged sequentially on the base substrate. The shielding conductive layer may include at least a shielding electrode and a plurality of shielding lines, the semiconductor layer may include at least active layers of the first transistor to the sixth transistor, the first conductive layer may include at least a first plate of the storage capacitor, the second conductive layer may include at least a second plate of the storage capacitor, the third conductive layer may include at least first electrodes and second electrodes of the first transistor to the sixth transistor, and the fourth conductive layer may include at least an anode connection electrode.

In an exemplary implementation, the base substrate may be a flexible base substrate, or a rigid base substrate. The rigid base substrate may include, but is not limited to, one or more of glass and quartz. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation mode, the flexible base substrate may include a first flexible material layer, a first inorganic material layer, a semiconductor layer, a second flexible material layer and a second inorganic material layer stacked on the glass carrier plate. Materials of the first flexible material layer and the second flexible material layer may be Polyimide (PI), Polyethylene Terephthalate (PET), or surface treated polymer soft film, etc., and materials of the first inorganic material layer and the second inorganic material layer may be Silicon Nitride (SiNx), Silicon Oxide (SiOx), or the like, for improving water and oxygen resistance of a base substrate. The first inorganic material layer and the second inorganic material layer may also be referred to as barrier layers, and the material of the semiconductor layer may be amorphous silicon. (a-si)

In an exemplary implementation mode, the first insulation layer, the second insulation layer, the third insulation layer, the fourth insulation layer, and the fifth insulation layer may be made of any one or more of silicon oxide (SiOx), silicon nitride (SiNx) and silicon oxynitride (SiON), and may be in a single layer, multiple layers, or a composite layer, the first insulation layer may be referred to as a buffer layer, the second and third insulation layers may be referred to as gate insulating (GI) layers, the fourth insulation layer may be referred to as an interlayer insulating (ILD) layer, and the fifth insulation layer may be referred to as a passivation (PVX) layer. The shielding conductive layer, the first conductive layer, the second conductive layer, the third conductive layer, and the fourth conductive layer may be made of a metal material such as silver (Ag), copper (Cu), aluminum (Al), titanium (Ti), molybdenum (Mo), etc., or may be made of an alloy material composed of metals, such as an aluminum-neodymium alloy (AlNd) or a molybdenum-niobium alloy (MoNb), etc., may be of a single-layer structure or a multi-layer composite structure, such as Ti/Al/Ti or the like. The first planarization layer and the second planarization layer may be made of an organic material such as resin or polyimide.

In an exemplary implementation, after the drive circuit layer has been prepared, a light emitting structure layer may be prepared on the drive circuit layer, and an encapsulation structure layer may be prepared on the light emitting structure layer, which will not be described further here.

As can be seen from the structure and preparation process of the display substrate described above, the pixel drive circuit of the present exemplary embodiment can meet the driving requirements by using six oxide transistors, which, compared with the existing pixel drive circuit structure with seven transistors, not only reduces the number of transistors, simplifies the structure of the pixel drive circuit structure, reduces the occupied area of the pixel drive circuit, and is beneficial to realizing high-resolution (PPI) display, but also ensures the yield of a large-size display substrate and reduces the production cost. According to the exemplary embodiment, the bottom gate electrode is arranged in the shielding conductive layer, and the top gate electrode is arranged in the first conductive layer, which can ensure the shielding effect and improve the electrical performance of the transistor. In the present disclosure, initial signal lines of a net connecting structure in the display region are constituted by arranging a first initial signal line extending along the first direction X and a second initial signal line extending along the second direction Y in the display region, which can minimize the resistance of the initial signal line, reduce the voltage drop of the initial voltage, effectively improve the uniformity of the initial voltage in the display substrate, effectively improve the display uniformity, and improve the display attribute and the display quality. In the present disclosure, a structure of VSS in pixel is achieved by arranging the low-voltage power supply line in the display region, which not only effectively reduces the resistance of the low-voltage power supply line, effectively reduces the voltage drop of the low-voltage power signal and realizes low power consumption, but also effectively improves the uniformity of the low-voltage power signals in the display substrate, effectively improves the display uniformity, and improves the display attribute and the display quality. The preparation process in the present disclosure may be compatible well with an existing preparation process, is simple in process implementation, is easy to implement, and has a high production efficiency, a low production cost, and a high yield.

The aforementioned structure shown in the present disclosure and the preparation process thereof are merely exemplary description. In an exemplary implementation mode, corresponding structures may be changed and patterning processes may be added or reduced according to actual needs, which is not limited here in the present disclosure. For example, the display substrate may include two first initial signal lines (such as a first horizontal initial line and a second horizontal initial line) extending along the first direction and two second initial signal lines (such as a first vertical initial line and a second vertical initial line) extending along the second direction. In at least one circuit unit, the first horizontal initial line and the first vertical initial line may be connected through a via, and the second horizontal initial line and the second vertical initial line may be connected through a via to form initial signal lines of a dual net connecting structure in the display region. As another example, the display substrate may include a first low-voltage power supply line extending along the first direction and a second low-voltage power supply line extending along the second direction. In at least one circuit unit, the first low-voltage power supply line and the second low-voltage power supply line are connected through a via to form low-voltage power supply lines of a net connecting structure in the display region.

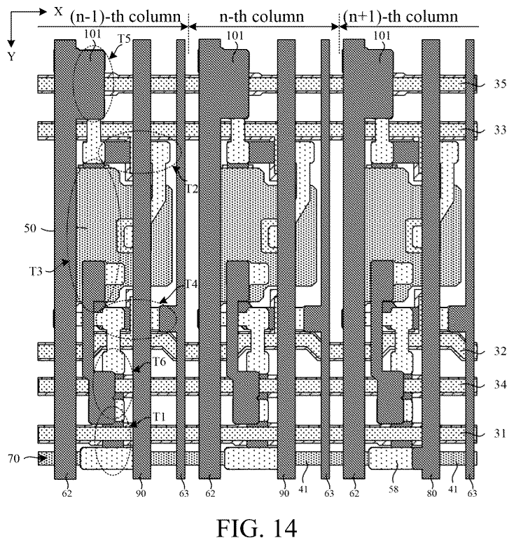

FIG. 14 illustrates a schematic diagram of a planar structure of another display substrate according to an exemplary embodiment of the present disclosure, illustrating a planar structure of pixel drive circuits in three circuit units in one unit row. As shown in FIG. 14, in an exemplary implementation mode, the body structure of the display substrate of the present exemplary embodiment is substantially the same as that of the display substrate shown in FIG. 5, except that in at least one circuit unit, a first shielding block 101 is provided on the first power supply line 62 in the fourth conductive layer.

In an exemplary implementation mode, the first shielding block 101 may be disposed at a side of the first power supply line 62 (close to the data signal line 63) in the first direction X, which is equivalent to providing a protrusion on the first power supply line 62, an orthographic projection of the first shielding block 101 on the base substrate overlaps at least partially with an orthographic projection of the fifth active layer of the fifth transistor T5 on the base substrate, and the first shielding block 101 is configured to shield the fifth transistor T5, reduce the influence of light on the electrical characteristics of the fifth transistor T5, and improve the operational stability of the fifth transistor T5.

In an exemplary implementation mode, the first shielding block 101 and the first power supply line 62 may be of an interconnected integral structure, and an orthographic projection of the first shielding block 101 on the base substrate overlaps at least partially with an orthographic projection of the channel region of the fifth active layer on the base substrate.

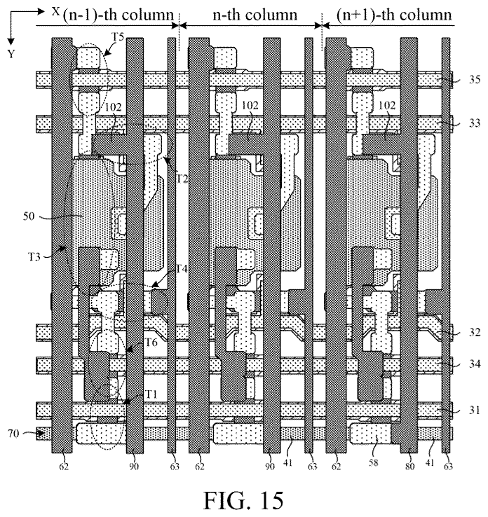

FIG. 15 is a schematic diagram of a planar structure of a still further display substrate according to an exemplary embodiment of the present disclosure, illustrating a planar structure of pixel drive circuits in three circuit units in one unit row. As shown in FIG. 15, in an exemplary implementation mode, the body structure of the display substrate of the present exemplary embodiment is substantially the same as that of the display substrate shown in FIG. 5, except that in at least one circuit unit, the second initial signal line 80 and/or the low-voltage power supply line 90 in the fourth conductive layer is provided with the second shielding block 102.

In an exemplary implementation mode, the second shielding block 102 may be disposed at a side of the second initial signal line 80 and/or the low-voltage power supply line 90 (close to the first power supply line 62) in an opposite direction of the first direction X, which is equivalent to providing a protrusion on the second initial signal line 80 and/or the low-voltage power supply line 90, an orthographic projection of the second shielding block 102 on the base substrate overlaps at least partially with an orthographic projection of the second active layer of the second transistor T2 on the base substrate, and the second shielding block 102 is configured to shield the second transistor T2 to reduce the influence of light on the electrical characteristics of the second transistor T2 and improve the operational stability of the second transistor T2.

In an exemplary implementation mode, the second shielding block 102 and the second initial signal line 80 of some circuit units may be of an interconnected integral structure, and the second shielding block 102 and the low-voltage power supply line 90 of some circuit units may be of an interconnected integral structure, and an orthographic projection of the second shielding block 102 on the base substrate at least partially overlaps with an orthographic projection of the channel region of the second active layer on the base substrate.

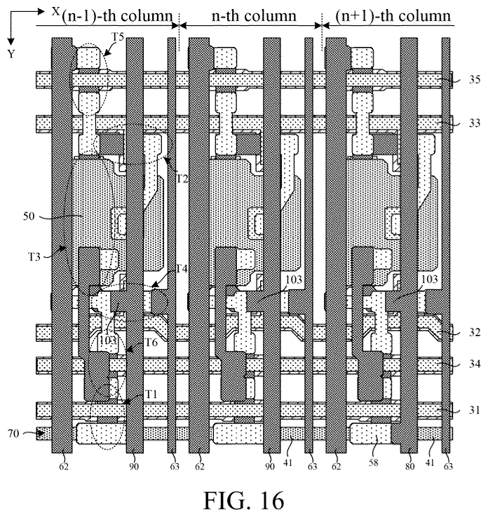

FIG. 16 is a schematic diagram of a planar structure of a still further display substrate according to an exemplary embodiment of the present disclosure, illustrating a planar structure of pixel drive circuits in three circuit units in one unit row. As shown in FIG. 16, in an exemplary implementation mode, the body structure of the display substrate of the present exemplary embodiment is substantially the same as that of the display substrate shown in FIG. 5, except that in at least one circuit unit, a third shielding block 103 is provided on the second initial signal line 80 and/or the low-voltage power supply line 90 in the fourth conductive layer.

In an exemplary implementation mode, the third shielding block 103 may be disposed at a side of the second initial signal line 80 and/or the low-voltage power supply line 90 (close to the first power supply line 62) in an opposite direction of the first direction X, which is equivalent to providing a protrusion on the second initial signal line 80 and/or the low-voltage power supply line 90, an orthographic projection of the third shielding block 103 on the base substrate overlaps at least partially with an orthographic projection of the fourth active layer of the fourth transistor T4 on the base substrate, and the third shielding block 103 is configured to shield the fourth transistor T4 to reduce the influence of light on the electrical characteristics of the fourth transistor T4 and improve the operational stability of the fourth transistor T4.

In an exemplary implementation mode, the third shielding block 103 and the second initial signal line 80 of some circuit units may be of an interconnected integral structure, and the third shielding block 103 and the low-voltage power supply line 90 of some circuit units may be of an interconnected integral structure, and an orthographic projection of the third shielding block 103 on the base substrate at least partially overlaps with an orthographic projection of the channel region of the fourth active layer on the base substrate.

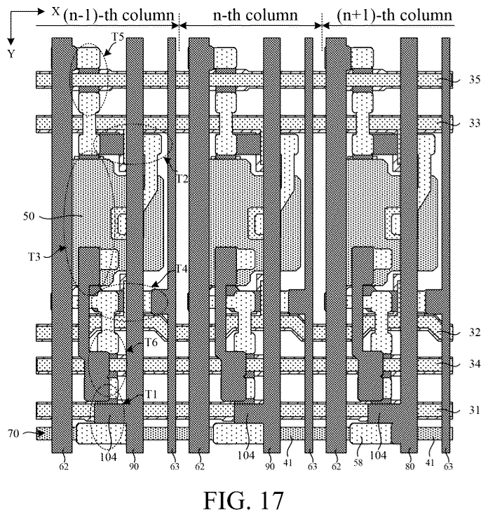

FIG. 17 is a schematic diagram of a planar structure of a still further display substrate according to an exemplary embodiment of the present disclosure illustrating a planar structure of pixel drive circuits in three circuit units in one unit row. As shown in FIG. 17, in an exemplary implementation mode, the body structure of the display substrate of the present exemplary embodiment is substantially the same as that of the display substrate shown in FIG. 5, except that in at least one circuit unit, a fourth shielding block 104 is provided on the second initial signal line 80 and/or the low-voltage power supply line 90 in the fourth conductive layer.

In an exemplary implementation mode, the fourth shielding block 104 may be disposed at a side of the second initial signal line 80 and/or the low-voltage power supply line 90 (close to the first power supply line 62) in an opposite direction of the first direction X, which is equivalent to providing a protrusion on the second initial signal line 80 and/or the low-voltage power supply line 90, an orthographic projection of the fourth shielding block 104 on the base substrate overlaps at least partially with an orthographic projection of the first active layer of the first transistor T1 on the base substrate, and the fourth shielding block 104 is configured to shield the first transistor T1 to reduce the influence of light on the electrical characteristics of the first transistor T1 and improve the operational stability of the first transistor T1.

In an exemplary implementation mode, the fourth shielding block 104 and the second initial signal line 80 of some circuit units may be of an interconnected integral structure, and the fourth shielding block 104 and the low-voltage power supply line 90 of some circuit units may be of an interconnected integral structure, and an orthographic projection of the fourth shielding block 104 on the base substrate at least partially overlaps with an orthographic projection of the channel region of the first active layer on the base substrate.

In some exemplary implementation modes, the fourth shielding block 104 may be disposed at a position of the first power supply line 62 close to the first transistor T1, which is equivalent to providing a protrusion on the first power supply line 62 to achieve shield for the first transistor T1.

In other exemplary implementation modes, the fourth shielding block 104 of some circuit units may be disposed on the first power supply line 62, the fourth shielding block 104 of some circuit units may be disposed on the second initial signal line 80, and the fourth shielding block 104 of some circuit units may be disposed on the low-voltage power supply line 90 according to the layout of the circuit unit, which is not limited here in the present disclosure.

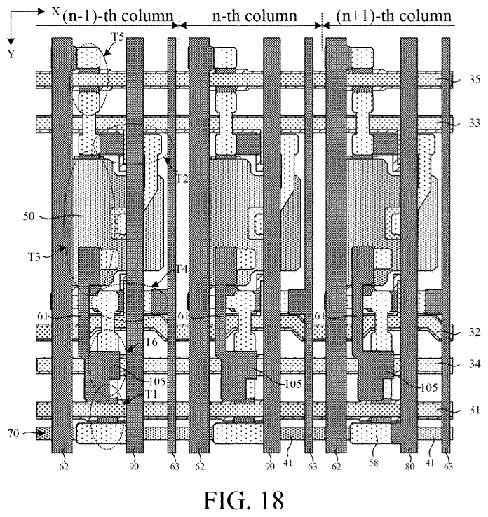

FIG. 18 is a schematic diagram of a planar structure of a still further display substrate according to an exemplary embodiment of the present disclosure, illustrating a planar structure of pixel drive circuits in three circuit units in one unit row. As shown in FIG. 18, in an exemplary implementation mode, the body structure of the display substrate of the present exemplary embodiment is substantially the same as that of the display substrate shown in FIG. 5, except that in at least one circuit unit, the fifth shielding block 105 is provided on the anode connection electrode 61 in the fourth conductive layer.

In an exemplary implementation mode, the fifth shielding block 105 may be disposed at a side of (close to the data signal line 63) of the anode connection electrode 61 in the first direction X, which is equivalent to increasing the size of the anode connection electrode 61, an orthographic projection of the fifth shielding block 105 on the base substrate overlaps at least partially with an orthographic projection of the sixth active layer of the sixth transistor T6 on the base substrate, and the fifth shielding block 105 is configured to shield the sixth transistor T6 to reduce the influence of light on the electrical characteristics of the sixth transistor T6 and improve the operational stability of the sixth transistor T6.

In an exemplary implementation mode, the fifth shielding block 105 and the anode connection electrode 61 may be of an interconnected integral structure, and an orthographic projection of the fifth shielding block 105 on the base substrate overlaps at least partially with an orthographic projection of the channel region of the sixth active layer on the base substrate.

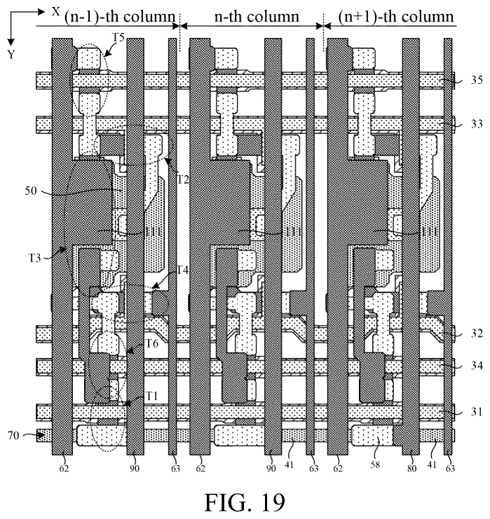

FIG. 19 is a schematic diagram of a planar structure of a still further display substrate according to an exemplary embodiment of the present disclosure, illustrating a planar structure of pixel drive circuits in three circuit units in one unit row. As shown in FIG. 19, in an exemplary implementation mode, the body structure of the display substrate of the present exemplary embodiment is substantially the same as that of the display substrate shown in FIG. 5, except that in at least one circuit unit, the shield block 111 is provided on the first power supply line 62 in the fourth conductive layer.

In an exemplary implementation mode, the shield block 111 may be disposed at a side of the first power supply line 62 in the first direction X (close to the data signal line 63), which is equivalent to providing a protrusion on the first power supply line 62, an orthographic projection of the shield block 111 on the base substrate overlaps at least partially with an orthographic projection of the second plate of the storage capacitor 50 on the base substrate, and the shield block 111 is configured to shield the fourth node N4 of the pixel drive circuit to stabilize the potential of the anode.

In an exemplary implementation mode, the shield block 111 and the first power supply line 62 may be of an interconnected integral structure.

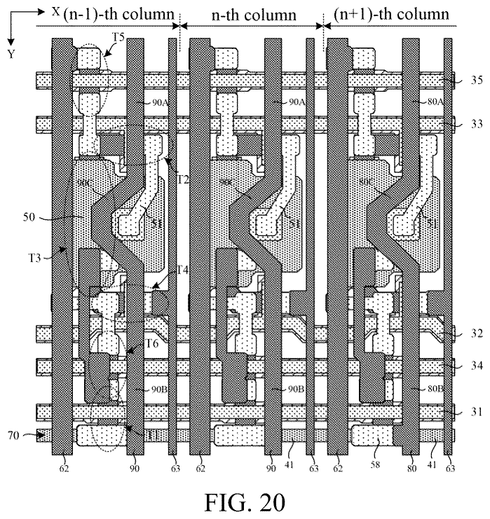

FIG. 20 is a schematic diagram of a planar structure of a still further display substrate according to an exemplary embodiment of the present disclosure, illustrating a planar structure of pixel drive circuits in three circuit units in one unit row. As shown in FIG. 20, in an exemplary implementation mode, the body structure of the display substrate of the present exemplary embodiment is substantially the same as that of the display substrate shown in FIG. 5, except that in at least one circuit unit, the second initial signal line 80 in the fourth conductive layer may include a first initial straight part 80A, a second initial straight part 80B, and an initial bending part 80C located between the first initial straight part 80A and the second initial straight part 80B, and/or the low-voltage power supply line 90 may include a first power supply straight part 90A, a second power supply straight part 90B, and a power supply bending part 90C located between the first power supply straight part 90A and the second power supply straight part 90B.

In an exemplary implementation mode, a first end of the initial bending part 80C is connected to the first initial straight part 80A, a second end of the initial bending part 80C is connected to the second initial straight part 80B, a middle portion of the initial bending part 80C protrudes in a direction close to the first power supply line 62 so that an orthographic projection of the second initial signal line 80 on the base substrate and an orthographic projection of the first connection electrode 51 (the first node N1 of the pixel drive circuit) on the base substrate do not overlap, and the initial bending part 80C of the second initial signal line 80 is configured to avoid the first node N1 of the pixel drive circuit to reduce a partial voltage of the first node N1 and improve potential stability of key nodes of the pixel drive circuit.

In an exemplary implementation mode, a first end of the power supply bending part 90C is connected to the first power supply straight part 90A, a second end of the power supply bending part 90C is connected to the second power supply straight part 90B, and a middle portion of the power supply bending part 90C protrudes in a direction close to the first power supply line 62 so that an orthographic projection of the low-voltage power supply line 90 on the base substrate and an orthographic projection of the first connection electrode 51 (the first node N1 of the pixel drive circuit) on the base substrate do not overlap, and the power supply bending part 90C of the low-voltage power supply line 90 is configured to avoid the first node N1 of the pixel drive circuit to reduce a partial voltage of the first node N1 and improve potential stability of key nodes of the pixel drive circuit.

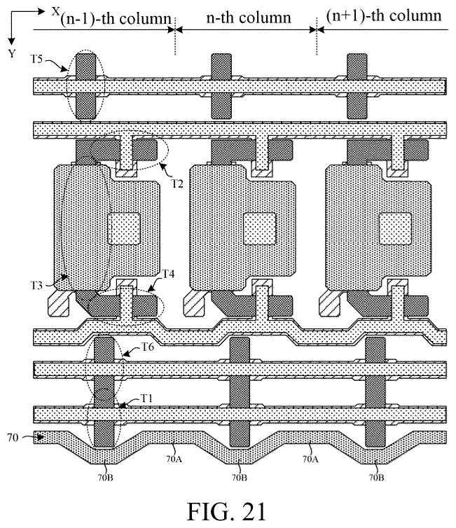

FIG. 21 is a schematic diagram of a planar structure of a still further display substrate according to an exemplary embodiment of the present disclosure, illustrating a planar structure of pixel drive circuits in three circuit units in one unit row. As shown in FIG. 21, in an exemplary implementation mode, the body structure of the display substrate of the present exemplary embodiment is substantially the same as the body structure of the display substrate shown in FIG. 5, except that a complete first initial signal line 70 is formed when the second conductive layer is formed.

In an exemplary implementation mode, the first initial signal lines 70 may have a shape of a bending line with a main body portion extending along the first direction X and the first initial signal lines 70 of adjacent circuit units are connected to each other.

In an exemplary implementation mode, the first initial signal line 70 may include an initial straight part 70A and an initial avoidance part 70B. The initial straight part 70A may be in a shape of a line extending along the first direction X and may be provided between adjacent first active layers in the first direction X. Two ends of the initial avoidance part 70B in the first direction X are respectively connected to the initial straight part 70A, and a middle portion of the initial avoidance part 70B protrudes in a direction away from the first active layer, so that an orthographic projection of the initial avoidance part 70B on the base substrate and an orthographic projection of the first active layer on the base substrate do not overlap.

In an exemplary implementation mode, the initial straight part 70A and the initial avoidance part 70B may be of an interconnected integral structure forming a complete first initial signal line 70. Since a complete first initial signal line 70 is formed when the second conductive layer is formed, corresponding vias and initial connection electrodes can be saved in the subsequent process, and the process difficulty can be reduced.

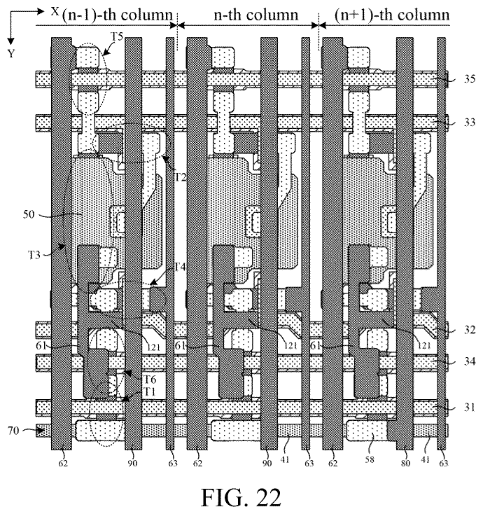

FIG. 22 is a schematic diagram of a planar structure of a still further display substrate according to an exemplary embodiment of the present disclosure, illustrating a planar structure of pixel drive circuits in three circuit units in one unit row. As shown in FIG. 22, in an exemplary implementation mode, the body structure of the display substrate of the present exemplary embodiment is substantially the same as that of the display substrate shown in FIG. 5, except that in at least one circuit unit, a first capacitor block 121 is provided on the anode connection electrode 61 in the fourth conductive layer.

In an exemplary implementation mode, the first capacitor block 121 may be disposed at a side of the anode connection electrode 61 in the first direction X (close to the data signal line 63), or may be disposed at a side of the anode connection electrode 61 in an opposite direction of the first direction x (close to the first power supply line 62), or may be disposed at two sides of the anode connection electrode 61 in the first direction X. An orthographic projection of the first capacitor block 121 on the base substrate overlaps at least partially with an orthographic projection of the second scan signal line 32 on the base substrate, and the first capacitor block 121 is configured to increase the parasitic capacitance between the anode connection electrode 61 (the fourth node n4 of the pixel drive circuit) and the second scan signal line 32.

In an exemplary implementation mode, by increasing the parasitic capacitance between the fourth node N4 of the pixel drive circuit and the second scan signal line 32, the falling edge of the signal on the second scan signal line 32 can pull down the potential of the fourth node N4 after the data writing is completed and before the light emitting element emits light, thereby enhancing the display effect of a black picture.

In an exemplary implementation mode, by providing the first capacitor block 121, the parasitic capacitance between the anode connection electrode 61 and the second scan signal line 32 is larger than the parasitic capacitance between the anode connection electrode 61 and the first light emitting control line 34.

In an exemplary implementation mode, the first capacitor block 121 and the anode connection electrode 61 may be of an interconnected integral structure.

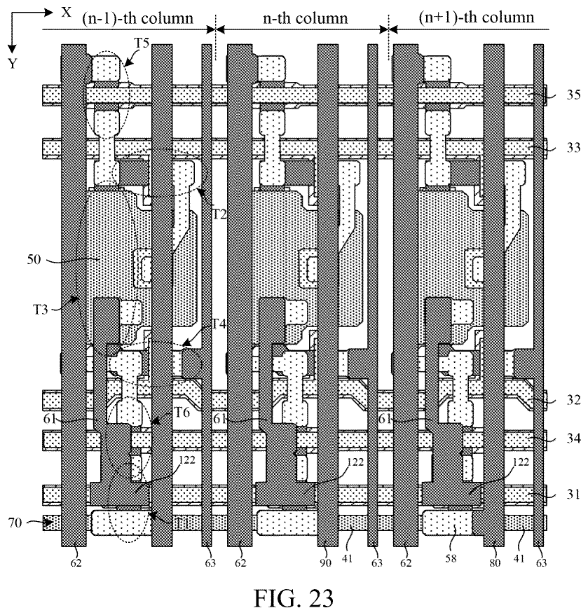

FIG. 23 is a schematic diagram of a planar structure of a still further display substrate according to an exemplary embodiment of the present disclosure illustrating a planar structure of pixel drive circuits in three circuit units in one unit row. As shown in FIG. 23, in an exemplary implementation mode, the body structure of the display substrate of the present exemplary embodiment is substantially the same as that of the display substrate shown in FIG. 5, except that in at least one circuit unit, a second capacitor block 122 is provided on the anode connection electrode 61 in the fourth conductive layer.

In an exemplary implementation mode, the second capacitor block 122 may be disposed at a side of the anode connection electrode 61 (close to the data signal line 63) in the first direction X, or may be disposed at a side of the anode connection electrode 61 in an opposite direction of the first direction X (close to the first power supply line 62), or may be disposed at two sides of the anode connection electrode 61 in the first direction X, an orthographic projection of the second capacitor block 122 on the base substrate overlaps at least partially with an orthographic projection of the first scan signal line 31 on the base substrate, and the second capacitor block 122 is configured to increase the parasitic capacitance between the anode connection electrode 61 (the fourth node N4 of the pixel drive circuit) and the first scan signal line 31.

In an exemplary implementation mode, by increasing the parasitic capacitance between the fourth node N4 of the pixel drive circuit and the first scan signal line 31, the potential of the fourth node N4 can be pulled down after the data writing is completed and before the light emitting element emits light, thereby enhancing the display effect of a black picture.

In an exemplary implementation mode, by providing the second capacitor block 122, the parasitic capacitance between the anode connection electrode 61 and the first scan signal line 31 is larger than the parasitic capacitance between the anode connection electrode 61 and the first light emitting control line 34.

In an exemplary implementation mode, the second capacitor block 122 and the anode connection electrode 61 may be of an interconnected integral structure.

In an exemplary implementation mode, the solutions shown in FIGS. 14 to 23 and the structures in the solutions can be combined randomly with each other, which is not limited here in the present disclosure.

In an exemplary implementation, the display substrate in the present disclosure may be applied to other display devices having pixel drive circuits, such as quantum dot displays and the like, which is not limited in the present disclosure.

The present disclosure also provides a preparation method for a display substrate, for preparing the display substrate according to the foregoing embodiments. In an exemplary implementation, the method may include the following acts.

A drive circuit layer is formed on a base substrate, the drive circuit layer includes a plurality of circuit units constituting a plurality of unit rows and a plurality of unit columns, a plurality of first initial signal lines extending along a first direction, and a plurality of second initial signal lines and low-voltage power supply lines extending along a second direction, the first direction intersects with the second direction, a circuit unit includes at least a pixel drive circuit, the pixel drive circuit includes a storage capacitor and a plurality of oxide transistors, a first initial signal line is configured to provide an initial voltage signal to the pixel drive circuit, the second initial signal lines are connected to the first initial signal lines, the first initial signal lines and the second initial signal lines constitute a net-like connecting structure.

A light emitting structure layer is formed on the drive circuit layer, the light emitting structure layer includes a plurality of light emitting devices, and the low-voltage power supply lines are configured to provide a low-power supply voltage signal to the light emitting devices.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, and this is not limited in the embodiments of the present invention.

Although the implementations disclosed in the present disclosure are described as above, the described contents are only implementations which are used for facilitating the understanding of the present disclosure, but are not intended to limit the present invention. Any skilled person in the art to which the present disclosure pertains may make any modifications and variations in forms and details of implementations without departing from the spirit and scope of the present disclosure. However, the patent protection scope of the present invention should be subject to the scope defined by the appended claims.

1. A display substrate comprising a drive circuit layer disposed on a base substrate and a light emitting structure layer disposed on a side of the drive circuit layer away from the base substrate, wherein the drive circuit layer comprises a plurality of circuit units constituting a plurality of unit rows and a plurality of unit columns, a plurality of first initial signal lines extending along a first direction, and a plurality of second initial signal lines and low-voltage power supply lines extending along a second direction, the first direction intersects with the second direction, a circuit unit comprises at least a pixel drive circuit, the pixel drive circuit comprises a storage capacitor and a plurality of oxide transistors, the light emitting structure layer comprises a plurality of light emitting devices, a first initial signal line is configured to provide an initial voltage signal to the pixel drive circuit, the low-voltage power supply lines are configured to provide a low-power supply voltage signal to the light emitting devices, the second initial signal lines are connected to the first initial signal lines, the first initial signal lines and the second initial signal lines constitute a net-like connecting structure.

2. The display substrate according to claim 12, wherein the first initial signal line comprises a plurality of initial sub-lines disposed at intervals along the first direction, and in at least one circuit unit, the initial sub-lines adjacent in the first direction are connected to each other through initial connection electrodes.

3. The display substrate according to claim 2, wherein the drive circuit layer comprises a plurality of conductive layers, the initial sub-lines and the initial connection electrodes are disposed in different conductive layers, in at least one circuit unit, an initial connection electrode is connected to an initial sub-line through a via.

4. The display substrate according to claim 2, wherein, in at least one circuit unit, a second initial signal line is connected to an initial connection electrode.

5. The display substrate according to claim 4, wherein the drive circuit layer comprises a plurality of conductive layers, the initial connection electrode and the second initial signal line are disposed in different conductive layers, in at least one circuit unit, the second initial signal line is connected to the initial connection electrode through a via.

6. The display substrate according to claim 1, wherein the pixel drive circuit comprises a first transistor, a second transistor, a third transistor, a fourth transistor, a fifth transistor, and a sixth transistor, in at least one circuit unit, a first electrode of the first transistor is connected to the first initial signal line, a second electrode of the first transistor is connected to a second plate of the storage capacitor and a second electrode of the sixth transistor, a first electrode of the second transistor is connected with a first plate of the storage capacitor, a second electrode of the second transistor is connected to a first electrode of the third transistor, a first electrode of the fourth transistor is connected to a data signal line, a second electrode of the fourth transistor is connected to a second electrode of the third transistor, a first electrode of the fifth transistor is connected to a first power supply line, a second electrode of the fifth transistor is connected with the first electrode of the third transistor, a first electrode of the sixth transistor is connected with the second electrode of the third transistor, and a second electrode of the sixth transistor is connected to a light emitting device.

7. The display substrate according to claim 6, wherein, in at least one circuit unit, the first transistor, the fourth transistor, and the sixth transistor are disposed at a side of the storage capacitor in the second direction, and the second transistor and the fifth transistor are disposed at a side of the storage capacitor in an opposite direction of the second direction.

8. The display substrate according to claim 7, wherein, in at least one circuit unit, the fourth transistor is disposed at the side of the storage capacitor in the second direction, the sixth transistor is disposed at a side of the fourth transistor away from the storage capacitor, the first transistor is disposed at a side of the sixth transistor away from the storage capacitor, the second transistor is disposed at the side of the storage capacitor in an opposite direction of the second direction, and the fifth transistor is disposed at a side of the second transistor away from the storage capacitor.

9. The display substrate according to claim 6, wherein, in at least one circuit unit, the first transistor comprises at least a first active layer, the sixth transistor comprises at least a sixth active layer, and a second region of the first active layer and a first region of the sixth active layer are of an interconnected integral structure.

10. The display substrate according to claim 6, wherein, in at least one circuit unit, the second transistor comprises at least a second active layer, the third transistor comprises at least a third active layer, the fourth transistor comprises at least a fourth active layer, the second active layer and the fourth active layer have a shape of a strip extending along the first direction, the third active layer has a shape of a strip extending along the second direction, a first region of the third active layer and a second region of the second active layer are of an interconnected integral structure, and a second region of the third active layer and a second region of the fourth active layer are of an interconnected integral structure.

11. The display substrate according to claim 6, wherein, in at least one circuit unit, the third transistor comprises at least a bottom gate electrode and a top gate electrode, the bottom gate electrode is connected to a second electrode of the fourth transistor and a first electrode of the sixth transistor, respectively, and the top gate electrode and a first plate of the storage capacitor are of an integral structure.

12. The display substrate according to claim 6, wherein the drive circuit layer further comprises a first scan signal line, a second scan signal line, a third scan signal line, a first light emitting control line and a second light emitting control line extending along the first direction, in at least one circuit unit, the first scan signal line is connected to a top gate electrode of the first transistor, the second scan signal line is connected to a top gate electrode of the fourth transistor, the third scan signal line is connected to a top gate electrode of the second transistor, the first light emitting control line is connected to a top gate electrode of the sixth transistor, and the second light emitting control line is connected to a top gate electrode of the fifth transistor.

13. The display substrate according to claim 12, wherein, in at least one circuit unit, the second scan signal line is located at a side of the storage capacitor in the second direction, the first light emitting control line is located at a side of the second scan signal line away from the storage capacitor, the first scan signal line is located at a side of the first light emitting control line away from the storage capacitor, the third scan signal line is located at a side of the storage capacitor in an opposite direction of the second direction, and the second light emitting control line is located at a side of the third scan signal line away from the storage capacitor.

14. The display substrate according to claim 13, wherein, in at least one circuit unit, the first initial signal line is disposed at a side of the first scan signal line away from the storage capacitor.

15. The display substrate according to claim 1, wherein the drive circuit layer comprises at least a shielding conductive layer, a first conductive layer, a second conductive layer, a third conductive layer and a fourth conductive layer arranged sequentially in a direction away from the base substrate, the shielding conductive layer comprises at least bottom gate electrodes of the plurality of oxide transistors, the first conductive layer comprises at least a first plate of the storage capacitor and top gate electrodes of the plurality of oxide transistors, the second conductive layer comprises at least a second plate of the storage capacitor and the first initial signal lines, the third conductive layer comprises at least first electrodes and second electrodes of the plurality of oxide transistors, and the fourth conductive layer comprises at least the second initial signal lines and the low-voltage power supply lines.

16. The display substrate according to claim 1, wherein the plurality of unit columns comprises at least a first unit column, a second unit column, and a third unit column, pixel drive circuits of a plurality of circuit units in the first unit column are connected to a red light emitting device that emits red light, pixel drive circuits of a plurality of circuit units in the second unit column are connected to a green light emitting device that emits green light, pixel drive circuits of a plurality of circuit units in the third unit column are connected to a blue light emitting device that emits blue light, the low-voltage power supply lines are provided in the first unit column and the second unit column, and the second initial signal lines are provided in the third unit column.

17. A display apparatus, comprising a display substrate according to claim 1.

18. A preparation method for a display substrate, comprising:
forming a drive circuit layer on a base substrate, wherein the drive circuit layer comprises a plurality of circuit units constituting a plurality of unit rows and a plurality of unit columns, a plurality of first initial signal lines extending along a first direction, and a plurality of second initial signal lines and low-voltage power supply lines extending along a second direction, the first direction intersects with the second direction, a circuit unit comprises at least a pixel drive circuit, the pixel drive circuit comprises a storage capacitor and a plurality of oxide transistors, a first initial signal line is configured to provide an initial voltage signal to the pixel drive circuit, the second initial signal lines are connected to the first initial signal lines, the first initial signal lines and the second initial signal lines constitute a net-like connecting structure;
forming a light emitting structure layer on the drive circuit layer, wherein the light emitting structure layer comprises a plurality of light emitting devices, and the low-voltage power supply lines are configured to provide a low-power supply voltage signal to the light emitting devices.

19. The display substrate according to claim 2, wherein the drive circuit layer comprises at least a shielding conductive layer, a first conductive layer, a second conductive layer, a third conductive layer and a fourth conductive layer arranged sequentially in a direction away from the base substrate, the shielding conductive layer comprises at least bottom gate electrodes of the plurality of oxide transistors, the first conductive layer comprises at least a first plate of the storage capacitor and top gate electrodes of the plurality of oxide transistors, the second conductive layer comprises at least a second plate of the storage capacitor and the first initial signal lines, the third conductive layer comprises at least first electrodes and second electrodes of the plurality of oxide transistors, and the fourth conductive layer comprises at least the second initial signal lines and the low-voltage power supply lines.

20. The display substrate according to claim 3, wherein the drive circuit layer comprises at least a shielding conductive layer, a first conductive layer, a second conductive layer, a third conductive layer and a fourth conductive layer arranged sequentially in a direction away from the base substrate, the shielding conductive layer comprises at least bottom gate electrodes of the plurality of oxide transistors, the first conductive layer comprises at least a first plate of the storage capacitor and top gate electrodes of the plurality of oxide transistors, the second conductive layer comprises at least a second plate of the storage capacitor and the first initial signal lines, the third conductive layer comprises at least first electrodes and second electrodes of the plurality of oxide transistors, and the fourth conductive layer comprises at least the second initial signal lines and the low-voltage power supply lines.
